(19) United States
(12) Patent Application Publication
(10) Pub. No.: US 2011/0240103 A1
(43) Pub. Date: Oct. 6, 2011

(54) SOLAR CELL INCLUDING A SILICONE RESIN LAYER

(75) Inventors: Bizhong Zhu, Midland, MI (US); Dimitris E. Katsoulis, Midland, MI (US)

(73) Assignee: Dow Corning Corporation

(21) Appl. No.: 12/303,311

(22) PCT Filed: Jul. 30, 2008
(86) PCT No.: PCT/US07/70231

§ 371 Date: Jun. 17, 2011

(51) Int. Cl. H01L 31/02; H01L 31/0256

(52) U.S. Cl. 136/252; 438/93; 257/E31.003

(57) ABSTRACT

The present invention provides a solar cell having a silicone resin layer. The solar cell comprises a silicone resin film that is at least partially cured and a photovoltaic element formed adjacent the silicone resin film.

### BACKGROUND OF THE INVENTION

1. Field of the Invention

This invention relates generally to solar cells and, more particularly, to forming solar cells adjacent to silicone polymer layers.

2. Description of the Related Art

Solar cells are used in a variety of contexts to convert the energy carried in radiation from the Sun into electrical energy that may be used immediately or stored in batteries for later use. There is a constant drive to reduce the weight and/or the size of solar cells so that they may be used in situations that require small, lightweight energy sources. Lightweight flexible thin-film solar cells have therefore been under development for many years. Thin-film solar cells are typically formed on a glass substrate or superstrate. Some work has also been reported in which thin-film solar cells have been fabricated on a polymeric substrate or superstrate. However, the fabrication processes that are used to form solar cells often involve high temperatures that may exceed the capabilities of common organic polymer films. For example, amorphous silicon photovoltaic cells are formed using processes that may expose organic polymer films to temperatures as high as 350° C. Most organic polymers breakdown or suffer other undesirable effects when exposed to temperatures that high.

Compositions comprising polyimides, such as Kapton®, may be able to withstand the high temperatures needed to form amorphous silicon photovoltaic cells. However, polyimides have other undesirable characteristics. For example, Kapton® may not be used as a superstrate because it is colored and its transparency is very limited. Polyimides also tend to degrade easily when exposed to radiation such as ultraviolet light and atomic oxygen. Polyimides also tend to absorb ambient moisture easily and exhibit high rates of outgassing during device fabrication under vacuum. Outgassing may cause dimensional changes in the structures and/or layers formed of the polyimides and the outgassed materials may contaminate subsequently formed layers in the solar cell.

### SUMMARY OF THE INVENTION

The present invention is directed to addressing the effects of one or more of the problems set forth above. The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

In one embodiment of the present invention, a solar cell having a silicone resin layer is provided. The solar cell comprises a silicone resin film that is at least partially cured and a photovoltaic element formed adjacent the silicone resin film.

### BRIEF DESCRIPTION OF THE DRAWINGS

The invention may be understood by reference to the following description taken in conjunction with the accompanying drawings, in which like reference numerals identify like elements, and in which:

FIGS. 1A, 1B, 1C, 1D, 1E, and 1F conceptually illustrate a first exemplary embodiment of a method of forming a solar cell, in accordance with one embodiment of the present invention;

FIGS. 2A, 2B, and 2C conceptually illustrate a second exemplary embodiment of a method of forming a solar cell, in accordance with the present invention; and

FIGS. 3A, 3B, and 3C conceptually illustrate a third exemplary embodiment of a method of forming a solar cell, in accordance with the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF SPECIFIC EMBODIMENTS

Illustrative embodiments of the invention are described below. In the interest of clarity, not all features of an actual implementation are described in this specification. It will of course be appreciated that in the development of any such actual embodiment, numerous implementation-specific decisions should be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

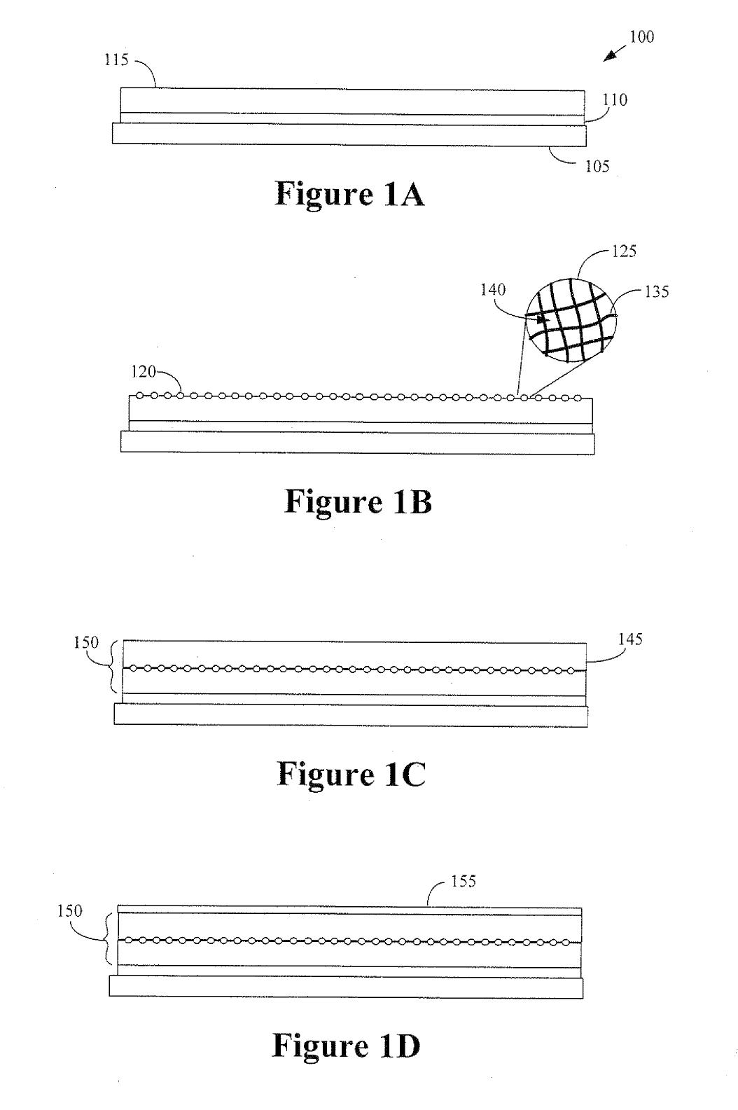

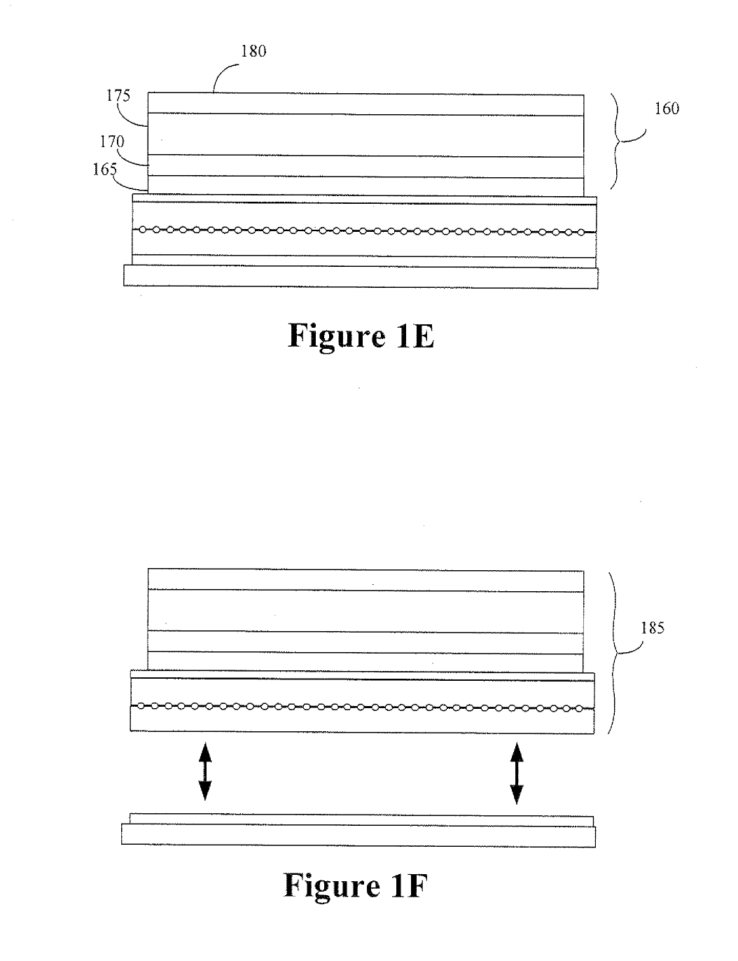

FIGS. 1A, 1B, 1C, 1D, 1E, and 1F conceptually illustrate a first exemplary embodiment of a method 200 of forming a solar cell. In the illustrated embodiment, a substrate 105 is treated to form a release layer 110 that is intended to decrease adherence of subsequently formed layers to the substrate 105 and to allow the subsequently formed layers to be released from the substrate 105. The release layer 110 can be any rigid or flexible material having a surface from which the reinforced silicone resin film can be removed without damage by delamination after the silicone resin is cured, as described below. Examples of release liners include, but are not limited to, Nylon, polyethyleneterephthalate, polyimide, PTFE, silicone, and sol gel coatings. For example, the substrate 105 may be a glass plate having dimensions of 6″×6″ that is treated with Relisse® 2520, from Nanofilm, Inc of Valley View. Ohio to form the release layer 110. However, persons of ordinary skill in the art having benefit of the present disclosure should appreciate that any material may be used to form the substrate 105 and/or the release layer 110. Furthermore, the release layer 105 is optional and not necessary for the practice of the present invention.

A layer of curable silicon-containing composition 115 is then deposited over the substrate 105 and (if present) the release layer 110, as shown in FIG. 1A. The layer of curable silicon-containing composition 115 may be deposited using conventional coating techniques, such as spin coating, dipping, spraying, brushing, or screen-printing. In one embodiment, the layer of curable silicon-containing composition 115 includes a resin, one or more cross-linkers, and a catalyst that are diluted with toluene. For example, the layer of curable silicon-containing composition 115 may be a solventless curable silicone resin formed using 10 g of a silicone resin [(PhSiO_{3/2})_{0.75}(ViMe₂SiO_{1/2})_{0.25}], 9.3 g of one or more cross-linkers, and a 0.1 g of a Pt catalyst diluted with toluene to 1000 ppm Pt from a Pt/(ViMe₂Si)₂O complex available from Dow Corning Corporation, Midland, Mich. This resin will be referred to as the 0-3015 resin in the text that follows.

The silicone resin used in the film of curable silicon-containing composition 115 may be a silicone resin having an average composition of (MeSiO_{3/2})_{0.4}(ViMe₂SiO_{1/2})_{0.6}, which may be formed by adding 100 g of MeSi(OMe)₃ and 100.4 g of (ViMe₂Si)₂O to a three-necked 500 ml flask equipped with a thermometer, a condenser, a Dean Stark trap, and a stirrer. Approximately 0.2 g of trifluoromethane sulfonic acid may then be added and the mixture stirred without heating for 30 minutes. Following the step, approximately 40 g of de-ionized water may be added and the mixture heated to 60° C. for 40 minutes. After cooling the mixture to below 40° C., approximately 0.2 g of CaCO₃ may be added and the mixture stirred for 2 hours. Then approximately 16 g of toluene may be added and the mixture heated to reflux. Methanol may be removed until the temperature reaches 85° C. After cooling the mixture to below 40° C., approximately 0.1 g of KOH aqueous solution may be added. The mixture may be heated to reflux and water continuously removed from the bottom of the condenser until substantially no water is coming out. The mixture may then be cooled to below 40° C. and approximately 0.11 g of vinyldimethylchlorosilane may be added. After stirring for half an hour the product may be filtered to remove precipitants. Residual toluene may be removed on a rotary evaporator at 80° C. and 5 mmHg.

The cross-linkers may include compositions including Me₃SiO(HMeSiO)₂SiMe₃. A crude supply of the cross-linker may be obtained from Dow Corning Corporation. However, the commercially available supply of the cross-linker typically contains a mixture of related components Me₃SiO(HMeSiO)ₙSiMe₃, with n ranging from 1 to 10. Thus, in one embodiment, a lab distillation unit with vacuum and a fractionation column may be used to separate the components. For example, the main useful component, Me₃SiO(HMeSiO)₂SiMe₃ may be the major product of the distillation process. In some embodiments, the other components Me₃SiO(HMeSiO)ₙSiMe₃ that have a higher degree of polymerization can also be used as cross-linkers.

The curable silicon-containing composition described above is only one example of a composition that may be used to form the layer 115. In alternative embodiments, the curable silicon-containing composition may be a hydrosilylation-curable silicone composition that can be any hydrosilylation-curable silicone composition comprising a silicone resin. Such compositions typically contain a silicone resin having silicon-bonded alkenyl groups or silicon-bonded hydrogen atoms, a cross-linking agent having silicon-bonded hydrogen atoms or silicon-bonded alkenyl groups capable of reacting with the silicon-bonded alkenyl groups or silicon-bonded hydrogen atoms in the resin, and a hydrosilylation catalyst. The silicone resin is typically a copolymer containing T and/or Q siloxane units in combination with M and/or D siloxane units. Moreover, the silicone resin can be a rubber-modified silicone resin, described below for the fifth and sixth embodiments of the silicone composition.

According to a first embodiment, the hydrosilylation-curable silicone composition comprises (A) a silicone resin having the formula (R¹R²₂SiO_{1/2})_{w}(R²₂SiO_{2/2})ₓ(R₁SiO_{3/2})_{y}(SiO_{4/2})_{z} (I), wherein R¹ is C1 to C10 hydrocarbyl or C1 to C10 halogen-substituted hydrocarbyl, both free of aliphatic unsaturation, R² is R¹ or alkenyl, w is from 0 to 0.8, x is from 0 to 0.6, y is from 0 to 0.99, z is from 0 to 0.75, w+x+y+z=1, y+z/(w+x+y+z) is from 0.2 to 0.99, and w+x/(w+x+y+z) is from 0.01 to 0.8, provided the silicone resin has an average of at least two silicon-bonded alkenyl groups per molecule; (B) an organosilicon compound having an average of at least two silicon-bonded hydrogen atoms per molecule in an amount sufficient to cure the silicone resin; and (C) a catalytic amount of a hydrosilylation catalyst.

Component (A) is at least one silicone resin having the formula (R¹R²₂SiO_{1/2})_{w}(R²₂SiO_{2/2})ₓ(R¹SiO_{3/2})_{y}(SiO_{4/2})_{z} (I), wherein R¹ is C1 to C10 hydrocarbyl or C1 to C10 halogen-substituted hydrocarbyl, both free of aliphatic unsaturation, R² is R¹ or alkenyl, w is from 0 to 0.8, x is from 0 to 0.6, y is from 0 to 0.99, z is from 0 to 0.75, w+x+y+z=1, y+z/(w+x+y+z) is from 0.2 to 0.99, and w+x/(w+x+y+z) is from 0.01 to 0.8, provided the silicone resin has an average of at least two silicon-bonded alkenyl groups per molecule.

The hydrocarbyl and halogen-substituted hydrocarbyl groups represented by R¹ are free of aliphatic unsaturation and typically have from 1 to 10 carbon atoms, alternatively from 1 to 6 carbon atoms. Acyclic hydrocarbyl and halogen-substituted hydrocarbyl groups containing at least 3 carbon atoms can have a branched or unbranched structure. Examples of hydrocarbyl groups represented by R¹ include, but are not limited to, alkyl, such as methyl, ethyl, propyl, 1-methylethyl, butyl, 1-methylpropyl, 2-methylpropyl, 1,1-dimethylethyl, pentyl, 1-methylbutyl, 1-ethylpropyl, 2-methylbutyl, 3-methylbutyl, 1,2-dimethylpropyl, 2,2-dimethylpropyl, hexyl, heptyl, octyl, nonyl, and decyl; cycloalkyl, such as cyclopentyl, cyclohexyl, and methylcyclohexyl; aryl, such as phenyl and naphthyl; alkaryl, such as tolyl and xylyl; and aralkyl, such as benzyl and phenethyl. Examples of halogen-substituted hydrocarbyl groups represented by R1 include, but are not limited to, 3,3,3-trifluoropropyl, 3-chloropropyl, chlorophenyl, dichlorophenyl, 2,2,2-trifluoroethyl, 2,2,3,3-tetrafluoropropyl, and 2,2,3,3,4,4,5,5-octafluoropentyl.

The alkenyl groups represented by R², which may be the same or different, typically have from 2 to about 10 carbon atoms, alternatively from 2 to 6 carbon atoms, and are exemplified by, but not limited to, vinyl, allyl, butenyl, hexenyl, and octenyl.

In the formula (I) of the silicone resin, the subscripts w, x, y, and z are mole fractions. The subscript w typically has a value of from 0 to 0.8, alternatively from 0.02 to 0.75, alternatively from 0.05 to 0.3; the subscript x typically has a value of from 0 to 0.6, alternatively from 0 to 0.45, alternatively from 0 to 0.25; the subscript y typically has a value of from 0 to 0.99, alternatively from 0.25 to 0.8, alternatively from 0.5 to 0.8; the subscript z typically has a value of from 0 to 0.75, alternatively from 0 to 0.55, alternatively from 0 to 0.25. Also, the ratio y+z/(w+x+y+z) is typically from 0.2 to 0.99, alternatively from 0.5 to 0.95, alternatively from 0.65 to 0.9. Further, the ratio w+x/(w+x+y+z) is typically from 0.01 to 0.80, alternatively from 0.05 to 0.5, alternatively from 0.1 to 0.35.

Typically at least 50 mol %, alternatively at least 65 mol %, alternatively at least 80 mol % of the groups R² in the silicone resin are alkenyl.

The silicone resin typically has a number-average molecular weight (Mn) of from 500 to 50,000, alternatively from 500 to 10,000, alternatively 1,000 to 3,000, where the molecular weight is determined by gel permeation chromatography employing a low angle laser light scattering detector, or a refractive index detector and silicone resin (MQ) standards.

The viscosity of the silicone resin at 25° C. is typically from 0.01 to 100,000 Pas, alternatively from 0.1 to 10,000 Pas, alternatively from 1 to 100 Pa·s.

The silicone resin typically contains less than 10% (w/w), alternatively less than 5% (w/w), alternatively less than 2% (w/w), of silicon-bonded hydroxy groups, as determined by ²⁹Si NMR.

The silicone resin contains R¹SiO_{3/2} units (i.e., T units) and/or SiO_{4/2} units (i.e., Q units) in combination with R¹R²₂SiO_{1/2} units (i.e., M units) and/or R²₂SiO_{2/2} units (i.e., D units), where R¹ and R² are as described and exemplified above. For example, the silicone resin can be a DT resin, an MT resin, an MDT resin, a DTQ resin, and MTQ resin, and MDTQ resin, a DQ resin, an MQ resin, a DTQ resin, an MTQ resin, or an MDQ resin.

Examples of silicone resins include, but are not limited to, resins having the following formulae:

(Vi₂MeSiO_{1/2})_{0.25}(PhSiO_{3/2})_{0.75}, (ViMe₂SiO_{1/2})_{0.25}(PhSiO_{3/2})_{0.75}, (ViMe₂SiO_{1/2})_{0.25}(MeSiO_{3/2})_{0.25}(PhSiO_{3/2})_{0.50}, (ViMe₂SiO_{1/2})_{0.15}(PhSiO_{3/2})_{0.75} (SiO_{4/2})_{0.1}, and (Vi₂MeSiO_{1/2})_{0.15}(ViMe₂SiO_{1/2})_{0.1}(PhSiO_{3/2})_{0.75}, where Me is methyl, Vi is vinyl, Ph is phenyl, and the numerical subscripts outside the parenthesis denote mole fractions. Also, in the preceding formulae, the sequence of units is unspecified.

Component (A) can be a single silicone resin or a mixture comprising two or more different silicone resins, each as described above.

Methods of preparing silicone resins are well known in the art; many of these resins are commercially available. Silicone resins are typically prepared by cohydrolyzing the appropriate mixture of chlorosilane precursors in an organic solvent, such as toluene. For example, a silicone resin consisting essentially of R¹R²₂SiO_{1/2} units and R¹SiO_{3/2} units can be prepared by cohydrolyzing a compound having the formula R¹R²₂SiCl and a compound having the formula R¹SiCl₃ in toluene, where R¹ and R² are as defined and exemplified above. The aqueous hydrochloric acid and silicone hydrolyzate are separated and the hydrolyzate is washed with water to remove residual acid and heated in the presence of a mild condensation catalyst to “body” the resin to the requisite viscosity. If desired, the resin can be further treated with a condensation catalyst in an organic solvent to reduce the content of silicon-bonded hydroxy groups. Alternatively, silanes containing hydrolysable groups other than chloro, such —Br, —I, —OCH₃, —OC(O)CH₃, —N(CH₃)₂, NHCOCH₃, and —SCH₃, can be utilized as starting materials in the cohydrolysis reaction. The properties of the resin products depend on the types of silanes, the mole ratio of silanes, the degree of condensation, and the processing conditions.

Component (B) is at least one organosilicon compound having an average of at least two silicon-bonded hydrogen atoms per molecule in an amount sufficient to cure the silicone resin of component (A).

The organosilicon compound has an average of at least two silicon-bonded hydrogen atoms per molecule, alternatively at least three silicon-bonded hydrogen atoms per molecule. It is generally understood that cross-linking occurs when the sum of the average number of alkenyl groups per molecule in component (A) and the average number of silicon-bonded hydrogen atoms per molecule in component (B) is greater than four.

The organosilicon compound can be an organohydrogensilane or an organohydrogensiloxane. The organohydrogensilane can be a monosilane, disilane, trisilane, or polysilane. Similarly, the organohydrogensiloxane can be a disiloxane, trisiloxane, or polysiloxane. The structure of the organosilicon compound can be linear, branched, cyclic, or resinous. Cyclosilanes and cyclosiloxanes typically have from 3 to 12 silicon atoms, alternatively from 3 to 10 silicon atoms, alternatively from 3 to 4 silicon atoms. In acyclic polysilanes and polysiloxanes, the silicon-bonded hydrogen atoms can be located at terminal, pendant, or at both terminal and pendant positions.

Examples of organohydrogensilanes include, but are not limited to, diphenylsilane, 2-chloroethylsilane, bis[(p-dimethylsilyl)phenyl]ether, 1,4-dimethyldisilylethane, 1,3,5-tris(dimethylsilyl)benzene, 1,3,5-trimethyl-1,3,5-trisilane, poly(methylsilylene)phenylene, and poly(methylsilylene)methylene.

The organohydrogensilane can also have the formula HR¹₂Si—R³—SiR¹₂H, wherein R¹ is C1 to C10 hydrocarbyl or C1 to C10 halogen-substituted hydrocarbyl, both free of aliphatic unsaturation, and R³ is a hydrocarbylene group free of aliphatic unsaturation having a formula selected from:

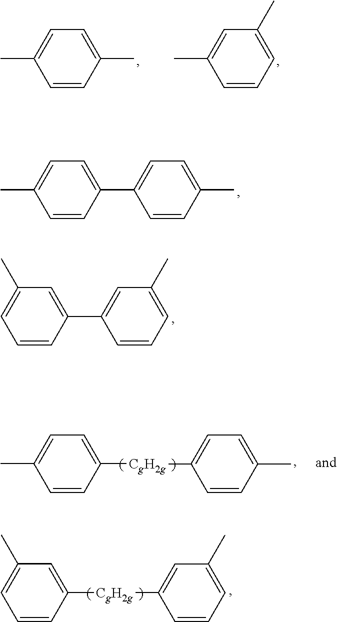

wherein g is from 1 to 6. The hydrocarbyl and halogen-substituted hydrocarbyl groups represented by R¹ are as defined and exemplified above for the silicone resin of component (A).

Examples of organohydrogensilanes having the formula HR¹₂Si—R³—SiR¹₂H, wherein R¹ and R³ are as described and exemplified above include, but are not limited to, silanes having the following formulae:

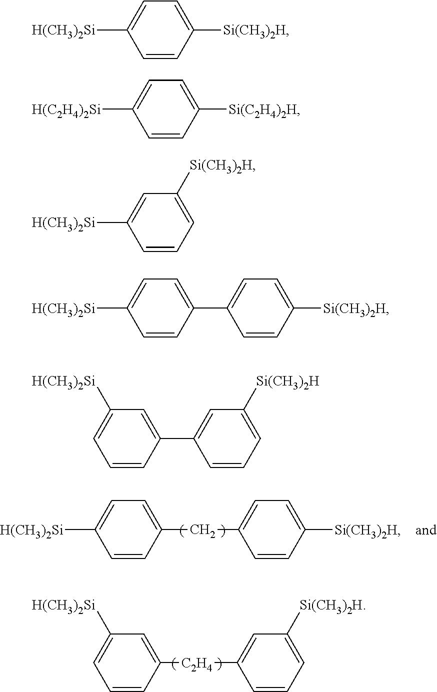

Examples of organohydrogensiloxanes include, but are not limited to, 1,1,3,3-tetramethyldisiloxane, -tetraphenyldisiloxane, phenyltris(dimethylsiloxy)silane, 1,3,5-trimethylcyclotrisiloxane, a trimethylsiloxy-terminated poly(methylhydrogensiloxane), a trimethylsiloxy-terminated poly(dimethylsiloxane/methylhydrogensiloxane), a dimethylhydrogensiloxy-terminated poly(methylhydrogensiloxane), and a resin consisting essentially of HMe₂SiO_{1/2} units, Me₃SiO_{1/2} units, and SiO_{4/2} units, wherein Me is methyl.

The organohydrogensiloxane can also be an organohydrogenpolysiloxane resin having the formula (R¹R⁴₂SiO_{1/2})_{w}(R⁴₂SiO_{2/2})ₓ(R¹SiO_{3/2})_{y}(SiO_{4/2})_{z} (II), wherein R¹ is C1 to C10 hydrocarbyl or C1 to C10 halogen-substituted hydrocarbyl, both free of aliphatic unsaturation, R⁴ is R¹ or an organosilylalkyl group having at least one silicon-bonded hydrogen atom, w is from 0 to 0.8, x is from 0 to 0.6, y is from 0 to 0.99, z is from 0 to 0.75, w+x+y+z=1, y+z/(w+x+y+z) is from 0.2 to 0.99, and w+x/(w+x+y+z) is from 0.01 to 0.8, provided at least 50 mol % of the groups R⁴ are organosilylalkyl.

The hydrocarbyl and halogen-substituted hydrocarbyl groups represented by R¹ are as described and exemplified above for the silicone resin of component (A). Examples of organosilylalkyl groups represented by R⁴ include, but are not limited to, groups having the following formulae:

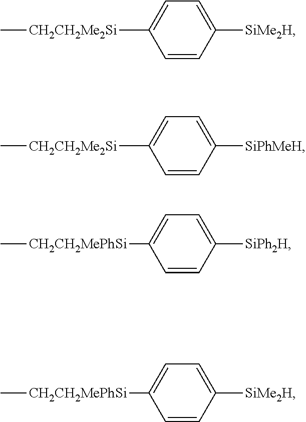

—CH₂CH₂SiMe₂H,
—CH₂CH₂SiMe₂CₙH₂ₙSiMe₂H,
—CH₂CH₂SiMe₂CₙH₂ₙSiMePhH,
—CH₂CH₂SiMePhH,
—CH₂CH₂SiPh₂H,
—CH₂CH₂SiMePhCₙH₂ₙSiPh₂H,
—CH₂CH₂SiMePhCₙH₂ₙSiMe₂H,
—CH₂CH₂SiMePhOSiMePhH, and
—CH₂CH₂SiMePhOSiPh(OSiMePhH)₂, where Me is methyl, Ph is phenyl, and the subscript n has a value of from 2 to 10.

In the formula (II) of the organohydrogenpolysiloxane resin, the subscripts w, x, y, and z are mole fractions. The subscript w typically has a value of from 0 to 0.8, alternatively from 0.02 to 0.75, alternatively from 0.05 to 0.3; the subscript x typically has a value of from 0 to 0.6, alternatively from 0 to 0.45, alternatively from 0 to 0.25; the subscript y typically has a value of from 0 to 0.99, alternatively from 0.25 to 0.8, alternatively from 0.5 to 0.8; the subscript z typically has a value of from 0 to 0.75, alternatively from 0 to 0.55, alternatively from 0 to 0.25. Also, the ratio y+z/(w+x+y+z) is typically from 0.2 to 0.99, alternatively from 0.5 to 0.95, alternatively from 0.65 to 0.9. Further, the ratio w+x/(w+x÷y+z) is typically from 0.01 to 0.80, alternatively from 0.05 to 0.5, alternatively from 0.1 to 0.35.

Typically, at least 50 mol %, alternatively at least 65 mol %, alternatively at least 80 mol % of the groups R⁴ in the organohydrogenpolysiloxane resin are organosilylalkyl groups having at least one silicon-bonded hydrogen atom.

The organohydrogenpolysiloxane resin typically has a number-average molecular weight (Mn) of from 500 to 50,000, alternatively from 500 to 10,000, alternatively 1,000 to 3,000, where the molecular weight is determined by gel permeation chromatography employing a low angle laser light scattering detector, or a refractive index detector and silicone resin (MQ) standards.

The organohydrogenpolysiloxane resin typically contains less than 10% (w/w), alternatively less than 5% (w/w), alternatively less than 2% (w/w), of silicon-bonded hydroxy groups, as determined by ²⁹Si NMR.

The organohydrogenpolysiloxane resin contains R¹SiO_{3/2} units (i.e., T units) and/or SiO_{4/2} units (i.e., Q units) in combination with R¹R⁴₂SiO_{1/2} units (i.e., M units) and/or R⁴₂SiO_{2/2} units (i.e., D units), where R¹ and R⁴ are as described and exemplified above. For example, the organohydrogenpolysiloxane resin can be a DT resin, an MT resin, an MDT resin, a DTQ resin, and MTQ resin, and MDTQ resin, a DQ resin, an MQ resin, a DTQ resin, an MTQ resin, or an MDQ resin.

Examples of organohydrogenpolysiloxane resins include, but are not limited to, resins having the following formulae:

((HMe₂SiC₆H₄SiMe₂CH₂CH₂)₂MeSiO_{1/2})_{0.12}(PhSiO_{3/2})_{0.88}, ((HMe₂SiC₆H₄SiMe₂CH₂CH₂)₂MeSiO_{1/2})_{0.17}(PhSiO_{3/2})_{0.83}, ((HMe₂SiC₆H₄SiMe₂CH₂CH₂)₂MeSiO_{1/2})_{0.17}(MeSiO_{3/2})_{0.17}(PhSiO_{3/2})_{0.66}, ((HMe₂SiC₆H₄SiMe₂CH₂CH₂)₂MeSiO_{1/2})_{0.15}(PhSiO_{3/2})_{0.75}(SiO_{4/2})_{0.10}, and ((HMe₂SiC₆H₄SiMe₂CH₂CH₂)₂MeSiO_{1/2})_{0.08}((HMe₂SiC₆H₄SiMe₂CH₂CH₂)Me₂SiO_{1/2})_{0.06} (PhSiO_{3/2})_{0.86}, where Me is methyl, Ph is phenyl, C₆H₄ denotes a para-phenylene group, and the numerical subscripts outside the parenthesis denote mole fractions. Also, in the preceding formulae, the sequence of units is unspecified.

Component (B) can be a single organosilicon compound or a mixture comprising two or more different organosilicon compounds, each as described above. For example, component (B) can be a single organohydrogensilane, a mixture of two different organohydrogensilanes, a single organohydrogensiloxane, a mixture of two different organohydrogensiloxanes, or a mixture of an organohydrogensilane and an organohydrogensiloxane. In particular, component (B) can be a mixture comprising at least 0.5% (w/w), alternatively at least 50% (w/w), alternatively at least 75% (w/w), based on the total weight of component (B), of the organohydrogenpolysiloxane resin having the formula (II), and an organohydrogensilane and/or organohydrogensiloxane, the latter different from the organohydrogenpolysiloxane resin.

The concentration of component (B) is sufficient to cure (cross-link) the silicone resin of component (A). The exact amount of component (B) depends on the desired extent of cure, which generally increases as the ratio of the number of moles of silicon-bonded hydrogen atoms in component (B) to the number of moles of alkenyl groups in component (A) increases. The concentration of component (B) is typically sufficient to provide from 0.4 to 2 moles of silicon-bonded hydrogen atoms, alternatively from 0.8 to 1.5 moles of silicon-bonded hydrogen atoms, alternatively from 0.9 to 1.1 moles of silicon-bonded hydrogen atoms, per mole of alkenyl groups in component (A).

Methods of preparing organosilicon compounds containing silicon-bonded hydrogen atoms are well known in the art. For example, organohydrogensilanes can be prepared by reaction of Grignard reagents with alkyl or aryl halides. In particular, organohydrogensilanes having the formula HR¹₂Si—R³—SiR¹₂H can be prepared by treating an aryl dihalide having the formula R³X₂ with magnesium in ether to produce the corresponding Grignard reagent and then treating the Grignard reagent with a chlorosilane having the formula HR¹₂SiCl, where R¹ and R³ are as described and exemplified above.

Methods of preparing organohydrogensiloxanes, such as the hydrolysis and condensation of organohalosilanes, are also well known in the art.

In addition, the organohydrogenpolysiloxane resin having the formula (II) can be prepared by reacting (a) a silicone resin having the formula (R¹R²₂SiO_{1/2})_{w}(R²₂SiO_{2/2})ₓ (R¹SiO_{3/2})_{y}(SiO_{4/2})_{z} (I) with (b) an organosilicon compound having an average of from two to four silicon-bonded hydrogen atoms per molecule and a molecular weight less than 1,000, in the presence of (c) a hydrosilylation catalyst and, optionally, (d) an organic solvent, wherein R¹ is C1 to C10 hydrocarbyl or C1 to C10 halogen-substituted hydrocarbyl, both free of aliphatic unsaturation, R² is R¹ or alkenyl, w is from 0 to 0.8, x is from 0 to 0.6, y is from 0 to 0.99, z is from 0 to 0.75, w+x+y+z=1, y+z/(w+x+y+z) is from 0.2 to 0.99, and w+x/(w+x+y+z) is from 0.01 to 0.8, provided the silicone resin (a) has an average of at least two silicon-bonded alkenyl groups per molecule, and the mole ratio of silicon-bonded hydrogen atoms in (b) to alkenyl groups in (a) is from 1.5 to 5.

Silicone resin (a) is as described and exemplified above for component (A) of the silicone composition. Silicone resin (a) can be the same as or different than the silicone resin used as component (A) in the hydrosilylation-curable silicone composition.

Organosilicon compound (b) is at least one organosilicon compound having an average of from two to four silicon-bonded hydrogen atoms per molecule. Alternatively, the organosilicon compound has an average of from two to three silicon-bonded hydrogen atoms per molecule. The organosilicon compound typically has a molecular weight less than 1,000, alternatively less than 750, alternatively less than 500. The silicon-bonded organic groups in the organosilicon compound are selected from hydrocarbyl and halogen-substituted hydrocarbyl groups, both free of aliphatic unsaturation, which are as described and exemplified above for R¹ in the formula of the silicone resin of component (A).

Organosilicon compound (b) can be an organohydrogensilane or an organohydrogensiloxane. The organohydrogensilane can be a monosilane, disilane, trisilane, or polysilane. Similarly, the organohydrogensiloxane can be a disiloxane, trisiloxane, or polysiloxane. The structure of the organosilicon compound can be linear, branched, or cyclic. Cyclosilanes and cyclosiloxanes typically have from 3 to 12 silicon atoms, alternatively from 3 to 10 silicon atoms, alternatively from 3 to 4 silicon atoms. In acyclic polysilanes and polysiloxanes, the silicon-bonded hydrogen atoms can be located at terminal, pendant, or at both terminal and pendant positions.

Examples of organohydrogensilanes include, but are not limited to, diphenylsilane, 2-chloroethylsilane, bis[(p-dimethylsilyl)phenyl]ether, 1,4-dimethyldisilylethane, 1,3,5-tris(dimethylsilyl)benzene, and 1,3,5-trimethyl-1,3,5-trisilane. The organohydrogensilane can also have the formula HR¹₂Si—R³—SiR¹₂H, wherein R¹ and R³ are as described and exemplified above.

Examples of organohydrogensiloxanes include, but are not limited to, 1,1,3,3-tetramethyldisiloxane, 1,1,3,3-tetraphenyldisiloxane, phenyltris(dimethylsiloxy)silane, and 1,3,5-trimethylcyclotrisiloxane.

Organosilicon compound (b) can be a single organosilicon compound or a mixture comprising two or more different organosilicon compounds, each as described above. For example, component (B) can be a single organohydrogensilane, a mixture of two different organohydrogensilanes, a single organohydrogensiloxane, a mixture of two different organohydrogensiloxanes, or a mixture of an organohydrogensilane and an organohydrogensiloxane.

Methods of preparing organohydrogensilanes, such as the reaction of Grignard reagents with alkyl or aryl halides, described above, are well known in the art. Similarly, methods of preparing organohydrogensiloxanes, such as the hydrolysis and condensation of organohalosilanes, are well known in the art.

Hydrosilylation catalyst (c) can be any of the well-known hydrosilylation catalysts comprising a platinum group metal (i.e., platinum, rhodium, ruthenium, palladium, osmium and iridium) or a compound containing a platinum group metal. Preferably, the platinum group metal is platinum, based on its high activity in hydrosilylation reactions.

Hydrosilylation catalysts include the complexes of chloroplatinic acid and certain vinyl-containing organosiloxanes disclosed by Willing in U.S. Pat. No. 3,419,593, which is hereby incorporated by reference. A catalyst of this type is the reaction product of chloroplatinic acid and 1,3-diethenyl-1,1,3,3-tetramethyldisiloxane.

The hydrosilylation catalyst can also be a supported hydrosilylation catalyst comprising a solid support having a platinum group metal on the surface thereof. A supported catalyst can be conveniently separated from the organohydrogenpolysiloxane resin product, for example, by filtering the reaction mixture. Examples of supported catalysts include, but are not limited to, platinum on carbon, palladium on carbon, ruthenium on carbon, rhodium on carbon, platinum on silica, palladium on silica, platinum on alumina, palladium on alumina, and ruthenium on alumina.

Organic solvent (d) is at least one organic solvent. The organic solvent can be any aprotic or dipolar aprotic organic solvent that does not react with silicone resin (a), organosilicon compound (b), or the organohydrogenpolysiloxane resin under the conditions of the present method, and is miscible with components (a), (b), and the organohydrogenpolysiloxane resin.

Examples of organic solvents include, but are not limited to, saturated aliphatic hydrocarbons such as n-pentane, hexane, n-heptane, isooctane and dodecane; cycloaliphatic hydrocarbons such as cyclopentane and cyclohexane; aromatic hydrocarbons such as benzene, toluene, xylene and mesitylene; cyclic ethers such as tetrahydrofuran (THF) and dioxane; ketones such as methyl isobutyl ketone (MIBK); halogenated alkanes such as trichloroethane; and halogenated aromatic hydrocarbons such as bromobenzene and chlorobenzene. Organic solvent (d) can be a single organic solvent or a mixture comprising two or more different organic solvents, each as described above.

The reaction can be carried out in any standard reactor suitable for hydrosilylation reactions. Suitable reactors include glass and Teflon-lined glass reactors. Preferably, the reactor is equipped with a means of agitation, such as stirring. Also, preferably, the reaction is carried out in an inert atmosphere, such as nitrogen or argon, in the absence of moisture.

The silicone resin, organosilicon compound, hydrosilylation catalyst, and, optionally, organic solvent, can be combined in any order. Typically, organosilicon compound (b) and hydrosilylation catalyst (c) are combined before the introduction of the silicone resin (a) and, optionally, organic solvent (d).

The reaction is typically carried out at a temperature of from 0 to 150° C., alternatively from room temperature (˜23±2° C.) to 115° C. When the temperature is less than 0° C., the rate of reaction is typically very slow.

The reaction time depends on several factors, such as the structures of the silicone resin and the organosilicon compound, and the temperature. The time of reaction is typically from 1 to 24 h at a temperature of from room temperature (˜23±2° C.) to 150° C. The optimum reaction time can be determined by routine experimentation

The mole ratio of silicon-bonded hydrogen atoms in organosilicon compound (b) to alkenyl groups in silicone resin (a) is typically from 1.5 to 5, alternatively from 1.75 to 3, alternatively from 2 to 2.5.

The concentration of hydrosilylation catalyst (c) is sufficient to catalyze the addition reaction of silicone resin (a) with organosilicon compound (b). Typically, the concentration of hydrosilylation catalyst (c) is sufficient to provide from 0.1 to 1000 ppm of a platinum group metal, alternatively from 1 to 500 ppm of a platinum group metal, alternatively from 5 to 150 ppm of a platinum group metal, based on the combined weight of silicone resin (a) and organosilicon compound (b). The rate of reaction is very slow below 0.1 ppm of platinum group metal. The use of more than 1000 ppm of platinum group metal results in no appreciable increase in reaction rate, and is therefore uneconomical.

The concentration of organic solvent (d) is typically from 0 to 99% (w/w), alternatively from 30 to 80% (w/w), alternatively from 45 to 60% (w/w), based on the total weight of the reaction mixture.

The organohydrogenpolysiloxane resin can be used without isolation or purification in the first embodiment of the hydrosilylation-curable silicone composition or the resin can be separated from most of the solvent by conventional methods of evaporation. For example, the reaction mixture can be heated under reduced pressure. Moreover, when the hydrosilylation catalyst used to prepare the organohydrogenpolysiloxane resin is a supported catalyst, described above, the resin can be readily separated from the hydrosilylation catalyst by filtering the reaction mixture. However, when the organohydrogenpolysiloxane resin is not separated from the hydrosilylation catalyst used to prepare the resin, the catalyst may be used as component (C) of the first embodiment of the hydrosilylation-curable silicone composition.

Component (C) of the hydrosilylation-curable silicone composition is at least one hydrosilylation catalyst that promotes the addition reaction of component (A) with component (B). The hydrosilylation catalyst can be any of the well-known hydrosilylation catalysts comprising a platinum group metal, a compound containing a platinum group metal, or a microencapsulated platinum group metal-containing catalyst. Platinum group metals include platinum, rhodium, ruthenium, palladium, osmium and iridium. Preferably, the platinum group metal is platinum, based on its high activity in hydrosilylation reactions.

Preferred hydrosilylation catalysts include the complexes of chloroplatinic acid and certain vinyl-containing organosiloxanes disclosed by Willing in U.S. Pat. No. 3,419,593, which is hereby incorporated by reference. A preferred catalyst of this type is the reaction product of chloroplatinic acid and 1,3-diethenyl-1,1,3,3-tetramethyldisiloxane.

The hydrosilylation catalyst can also be a microencapsulated platinum group metal-containing catalyst comprising a platinum group metal encapsulated in a thermoplastic resin. Compositions containing microencapsulated hydrosilylation catalysts are stable for extended periods of time, typically several months or longer, under ambient conditions, yet cure relatively rapidly at temperatures above the melting or softening point of the thermoplastic resin(s). Microencapsulated hydrosilylation catalysts and methods of preparing them are well known in the art, as exemplified in U.S. Pat. No. 4,766,176 and the references cited therein; and U.S. Pat. No. 5,017,654.

Component (C) can be a single hydrosilylation catalyst or a mixture comprising two or more different catalysts that differ in at least one property, such as structure, form, platinum group metal, complexing ligand, and thermoplastic resin.

The concentration of component (C) is sufficient to catalyze the addition reaction of component (A) with component (B). Typically, the concentration of component (C) is sufficient to provide from 0.1 to 1000 ppm of a platinum group metal, preferably from 1 to 500 ppm of a platinum group metal, and more preferably from 5 to 150 ppm of a platinum group metal, based on the combined weight of components (A) and (B). The rate of cure is very slow below 0.1 ppm of platinum group metal. The use of more than 1000 ppm of platinum group metal results in no appreciable increase in cure rate, and is therefore uneconomical.

According to a second embodiment, the hydrosilylation-curable silicone composition comprises (A′) a silicone resin having the formula (R¹R⁵₂SiO_{1/2})_{w}(R⁵₂SiO_{2/2})ₓ(R⁵SiO_{3/2})_{y}(SiO_{4/2})_{z} (III), wherein R¹ is C1 to C10 hydrocarbyl or C1 to C10 halogen-substituted hydrocarbyl, both free of aliphatic unsaturation, R⁵ is R¹ or —H, w is from 0 to 0.8, x is from 0 to 0.6, y is from 0 to 0.99, z is from 0 to 0.75, w+x+y+z=1, y+z/(w+x+y+z) is from 0.2 to 0.99, and w+x/(w+x+y+z) is from 0.01 to 0.8, provided the silicone resin has an average of at least two silicon-bonded hydrogen atoms per molecule; (B′) an organosilicon compound having an average of at least two silicon-bonded alkenyl groups per molecule in an amount sufficient to cure the silicone resin; and (C) a catalytic amount of a hydrosilylation catalyst.

Component (A′) is at least one silicone resin having the formula (R¹R⁵₂SiO_{1/2})_{w}(R⁵₂SiO_{2/2})ₓ(R⁵SiO_{3/2})_{y}(SiO_{4/2})_{z} (III), wherein R¹ is C1 to C10 hydrocarbyl or C1 to C10 halogen-substituted hydrocarbyl, both free of aliphatic unsaturation, R⁵ is R¹ or —H, w is from 0 to 0.8, x is from 0 to 0.6, y is from 0 to 0.99, z is from 0 to 0.75, w+x+y+z=1, y+z/(w+x+y+z) is from 0.2 to 0.99, and w+x/(w+x+y+z) is from 0.01 to 0.8, provided the silicone resin has an average of at least two silicon-bonded hydrogen atoms per molecule. In the formula (III), R¹, w, x, y, z, y+z/(w+x+y+z), and w+x/(w+x+y+z) are as described and exemplified above for the silicone resin having the formula (I).

Typically at least 50 mol %, alternatively at least 65 mol %, alternatively at least 80 mol % of the groups R⁵ in the silicone resin are hydrogen.

The silicone resin typically has a number-average molecular weight (Mn) of from 500 to 50,000, alternatively from 500 to 10,000, alternatively 1,000 to 3,000, where the molecular weight is determined by gel permeation chromatography employing a low angle laser light scattering detector, or a refractive index detector and silicone resin (MQ) standards.

The viscosity of the silicone resin at 25° C. is typically from 0.01 to 100,000 Pa·s, alternatively from 0.1 to 10,000 Pa·s, alternatively from 1 to 100 Pa·s.

The silicone resin typically contains less than 10% (w/w), alternatively less than 5% (w/w), alternatively less than 2% (w/w), of silicon-bonded hydroxy groups, as determined by ²⁹Si NMR.

The silicone resin contains R⁵SiO_{3/2} units (i.e., T units) and/or SiO₂₄ units (i.e., Q units) in combination with R¹R⁵₂SiO_{1/2} units (i.e., M units) and/or R⁵₂SiO_{2/2} units (i.e., D units). For example, the silicone resin can be a DT resin, an MT resin, an MDT resin, a DTQ resin, and MTQ resin, and MDTQ resin, a DQ resin, an MQ resin, a DTQ resin, an MTQ resin, or an MDQ resin.

Examples of silicone resins suitable for use as component (A′) include, but are not limited to, resins having the following formulae:

(HMe₂SiO_{1/2})_{0.25}(PhSiO_{3/2})_{0.75}, (HMeSiO_{2/2})_{0.3}(PhSiO_{3/2})_{0.6}(MeSiO_{3/2})_{0.1}, and (Me₃SiO_{1/2})_{0.1}(H₂SiO_{2/2})_{0.1}(MeSiO_{3/2})_{0.4}(PhSiO_{3/2})_{0.4}, where Me is methyl, Ph is phenyl, and the numerical subscripts outside the parenthesis denote mole fractions. Also, in the preceding formulae, the sequence of units is unspecified.

Component (A′) can be a single silicone resin or a mixture comprising two or more different silicone resins, each as described above.

Methods of preparing silicone resins containing silicon-bonded hydrogen atoms are well known in the art; many of these resins are commercially available. Silicone resins are typically prepared by cohydrolyzing the appropriate mixture of chlorosilane precursors in an organic solvent, such as toluene. For example, a silicone resin consisting essentially of R¹R⁵₂SiO_{1/2} units and R⁵SiO_{3/2} units can be prepared by cohydrolyzing a compound having the formula R¹R⁵₂SiCl and a compound having the formula R⁵SiCl₃ in toluene, where R¹ and R⁵ are as described and exemplified above. The aqueous hydrochloric acid and silicone hydrolyzate are separated and the hydrolyzate is washed with water to remove residual acid and heated in the presence of a mild non-basic condensation catalyst to “body” the resin to the requisite viscosity. If desired, the resin can be further treated with a non-basic condensation catalyst in an organic solvent to reduce the content of silicon-bonded hydroxy groups. Alternatively, silanes containing hydrolysable groups other than chloro, such —Br, —I, —OCH₃, —OC(O)CH₃, —N(CH₃)₂, NHCOCH₃, and —SCH₃, can be utilized as starting materials in the cohydrolysis reaction. The properties of the resin products depend on the types of silanes, the mole ratio of silanes, the degree of condensation, and the processing conditions.

Component (B′) is at least one organosilicon compound having an average of at least two silicon-bonded alkenyl groups per molecule in an amount sufficient to cure the silicone resin of component (A′).

The organosilicon compound contains an average of at least two silicon-bonded alkenyl groups per molecule, alternatively at least three silicon-bonded alkenyl groups per molecule. It is generally understood that cross-linking occurs when the sum of the average number of silicon-bonded hydrogen atoms per molecule in component (A′) and the average number of silicon-bonded alkenyl groups per molecule in component (B′) is greater than four.

The organosilicon compound can be an organosilane or an organosiloxane. The organosilane can be a monosilane, disilane, trisilane, or polysilane. Similarly, the organosiloxane can be a disiloxane, trisiloxane, or polysiloxane. The structure of the organosilicon compound can be linear, branched, cyclic, or resinous. Cyclosilanes and cyclosiloxanes typically have from 3 to 12 silicon atoms, alternatively from 3 to 10 silicon atoms, alternatively from 3 to 4 silicon atoms. In acyclic polysilanes and polysiloxanes, the silicon-bonded alkenyl groups can be located at terminal, pendant, or at both terminal and pendant positions.

Examples of organosilanes suitable for use as component (B′) include, but are not limited to, silanes having the following formulae:

Vi₄Si, PhSiVi₃, MeSiVi₃, PhMeSiVi₂, Ph₂SiVi₂, and PhSi(CH₂CH═CH₂)₃, where Me is methyl, Ph is phenyl, and Vi is vinyl.

Examples of organosiloxanes suitable for use as component (B′) include, but are not limited to, siloxanes having the following formulae:

PhSi(OSiMe₂Vi)₃, Si(OSiMe₂Vi)₄, MeSi(OSiMe₂Vi)₃, and Ph₂Si(OSiMe₂Vi)₂, where Me is methyl, and Ph is phenyl.

Component (B′) can be a single organosilicon compound or a mixture comprising two or more different organosilicon compounds, each as described above. For example component (B′) can be a single organosilane, a mixture of two different organosilanes, a single organosiloxane, a mixture of two different organosiloxanes, or a mixture of an organosilane and an organosiloxane.

The concentration of component (B′) is sufficient to cure (cross-link) the silicone resin of component (A′). The exact amount of component (B′) depends on the desired extent of cure, which generally increases as the ratio of the number of moles of silicon-bonded alkenyl groups in component (B′) to the number of moles of silicon-bonded hydrogen atoms in component (A′) increases. The concentration of component (a) is typically sufficient to provide from 0.4 to 2 moles of silicon-bonded alkenyl groups, alternatively from 0.8 to 1.5 moles of silicon-bonded alkenyl groups, alternatively from 0.9 to 1.1 moles of silicon-bonded alkenyl groups, per mole of silicon-bonded hydrogen atoms in component (A′).

Methods of preparing organosilanes and organosiloxanes containing silicon-bonded alkenyl groups are well known in the art; many of these compounds are commercially available.

Component (C) of the second embodiment of the silicone composition is as described and exemplified above for component (C) of the first embodiment.

According to a third embodiment, the hydrosilylation-curable silicone composition comprises (A) a silicone resin having the formula (R¹R²₂SiO_{1/2})_{w}(R²₂SiO_{2/2})ₓ(R¹SiO_{3/2})_{y}(SiO_{4/2})_{z} (I); (B) an organosilicon compound having an average of at least two silicon-bonded hydrogen atoms per molecule in an amount sufficient to cure the silicone resin; (C) a catalytic amount of a hydrosilylation catalyst; and (D) a silicone rubber having a formula selected from (i) R¹R²₂SiO(R²₂SiO)ₐSiR²₂R¹ (IV) and (ii) R⁵R¹₂SiO(R¹R⁵SiO)_{b}SiR¹₂R⁵ (V); wherein R¹ is C1 to C10 hydrocarbyl or C1 to C10 halogen-substituted hydrocarbyl, both free of aliphatic unsaturation, R² is R¹ or alkenyl, R⁵ is R¹ or —H subscripts a and b each have a value of from 1 to 4, w is from 0 to 0.8, x is from 0 to 0.6, y is from 0 to 0.99, z is from 0 to 0.75, w+x+y+z=1, y+z/(w+x+y+z) is from 0.2 to 0.99, and w+x/(w+x+y+z) is from 0.01 to 0.8, provided the silicone resin and the silicone rubber (D)(i) each have an average of at least two silicon-bonded alkenyl groups per molecule, the silicone rubber (D)(ii) has an average of at least two silicon-bonded hydrogen atoms per molecule, and the mole ratio of silicon-bonded alkenyl groups or silicon-bonded hydrogen atoms in the silicone rubber (D) to silicon-bonded alkenyl groups in the silicone resin (A) is from 0.01 to 0.5.

Components (A), (B), and (C) of the third embodiment of the silicone composition are as described and exemplified above for the first embodiment.

The concentration of component (B) is sufficient to cure (cross-link) the silicone resin of component (A). When component (D) is (D)(i), the concentration of component (B) is such that the ratio of the number of moles of silicon-bonded hydrogen atoms in component (B) to the sum of the number of moles of silicon-bonded alkenyl groups in component (A) and component (D)(i) is typically from 0.4 to 2, alternatively from 0.8 to 1.5, alternatively from 0.9 to 1.1. Furthermore, when component (D) is (D)(ii), the concentration of component (B) is such that the ratio of the sum of the number of moles of silicon-bonded hydrogen atoms in component (B) and component (D)(ii) to the number of moles of silicon-bonded alkenyl groups in component (A) is typically from 0.4 to 2, alternatively from 0.8 to 1.5, alternatively from 0.9 to 1.1.

Component (D) is a silicone rubber having a formula selected from (i) R¹R²₂SiO(R²₂SiO)ₐSiR²₂R¹ (IV) and (ii) R⁵R¹₂SiO(R¹R⁵SiO)_{b} SiR¹₂ R⁵ (V); wherein R¹ is C1 to C10 hydrocarbyl or C1 to C10 halogen-substituted hydrocarbyl, both free of aliphatic unsaturation, R² is R¹ or alkenyl, R⁵ is R¹ or —H, and subscripts a and b each have a value of from 1 to 4, provided the silicone rubber (D)(i) has an average of at least two silicon-bonded alkenyl groups per molecule, and the silicone rubber (D)(ii) has an average of at least two silicon-bonded hydrogen atoms per molecule.

Component (D)(i) is at least one silicone rubber having the formula R¹R²₂SiO(R²₂SiO)ₐSiR²₂R¹ (IV), wherein R¹ and R² are as described and exemplified above and the subscript a has a value of from 1 to 4, provided the silicone rubber (D)(i) has an average of at least two silicon-bonded alkenyl groups per molecule. Alternatively, the subscript a has a value of from 2 to 4 or from 2 to 3.

Examples of silicone rubbers suitable for use as component (D)(i) include, but are not limited to, silicone rubbers having the following formulae:

ViMe₂SiO(Me₂SiO)ₐSiMe₂Vi, ViMe₂SiO(Ph₂SiO)ₐSiMe₂Vi, and ViMe₂SiO(PhMeSiO)ₐSiMe₂Vi, where Me is methyl, Ph is phenyl, Vi is vinyl, and the subscript a has a value of from 1 to 4.

Component (D)(i) can be a single silicone rubber or a mixture comprising two or more different silicone rubbers, each having the formula (IV).

Component (D)(ii) is at least one silicone rubber having the formula R⁵R¹₂SiO (R¹R⁵SiO)_{b}SiR¹₂R⁵ (V); wherein R¹ and R⁵ are as described and exemplified above, and the subscript b has a value of from 1 to 4, provided the silicone rubber (D)(ii) has an average of at least two silicon-bonded hydrogen atoms per molecule. Alternatively, the subscript b has a value of from 2 to 4 or from 2 to 3.

Examples of silicone rubbers suitable for use as component (D)(ii) include, but are not limited to, silicone rubbers having the following formulae:

HMe₂SiO(Me₂SiO)_{b}SiMe₂H, HMe₂SiO(Ph₂SiO)_{b}SiMe₂H, HMe₂SiO(PhMeSiO)_{b}SiMe₂H, and HMe₂SiO(Ph₂SiO)₂(Me₂SiO)₂SiMe₂H, where Me is methyl, Ph is phenyl, and the subscript b has a value of from 1 to 4.

Component (D)(ii) can be a single silicone rubber or a mixture comprising two or more different silicone rubbers, each having the formula (V).

The mole ratio of silicon-bonded alkenyl groups or silicon-bonded hydrogen atoms in the silicone rubber (D) to silicon-bonded alkenyl groups in the silicone resin (A) is typically from 0.01 to 0.5, alternatively from 0.05 to 0.4, alternatively from 0.1 to 0.3.

Methods of preparing silicone rubbers containing silicon-bonded alkenyl groups or silicon-bonded hydrogen atoms are well known in the art; many of these compounds are commercially available.

According to a fourth embodiment, the hydrosilylation-curable silicone composition comprises (A′) a silicone resin having the formula (R¹R⁵₂SiO_{1/2})_{w}(R⁵₂SiO_{2/2})ₓ(R⁵SiO_{3/2})_{y}(SiO_{4/2})_{z} (III); (B′) an organosilicon compound having an average of at least two silicon-bonded alkenyl groups per molecule in an amount sufficient to cure the silicone resin; (C) a catalytic amount of a hydrosilylation catalyst; and (D) a silicone rubber having a formula selected from (i) R¹R²₂SiO(R²₂SiO)ₐSiR²₂R¹ (IV) and (ii) R⁵R¹₂SiO(R¹R⁵SiO)_{b}SiR¹₂R₅ (V); wherein R¹ is C1 to C10 hydrocarbyl or C1 to C10 halogen-substituted hydrocarbyl, both free of aliphatic unsaturation, R² is R¹ or alkenyl, R⁵ is R¹ or —H, subscripts a an b each have a value of from 1 to 4, w is from 0 to 0.8, x is from 0 to 0.6, y is from 0 to 0.99, z is from 0 to 0.75, w+x+y+z=1, y+z/(w+x+y+z) is from 0.2 to 0.99, and w+x/(w+x+y+z) is from 0.01 to 0.8, provided the silicone resin and the silicone rubber (D)(ii) each have an average of at least two silicon-bonded hydrogen atoms per molecule, the silicone rubber (D)(i) has an average of at least two silicon-bonded alkenyl groups per molecule, and the mole ratio of silicon-bonded alkenyl groups or silicon-bonded hydrogen atoms in the silicone rubber (D) to silicon-bonded hydrogen atoms in the silicone resin (A′) is from 0.01 to 0.5.

Components (A′), (B′), and (C) of the fourth embodiment of the silicone composition are as described and exemplified above for the second embodiment, and component (D) of the fourth embodiment is as described and exemplified above for the third embodiment.

The concentration of component (B′) is sufficient to cure (cross-link) the silicone resin of component (A′). When component (D) is (D)(i), the concentration of component (B′) is such that the ratio of the sum of the number of moles of silicon-bonded alkenyl groups in component (B′) and component (D)(i) to the number of moles of silicon-bonded hydrogen atoms in component (A′) is typically from 0.4 to 2, alternatively from 0.8 to 1.5, alternatively from 0.9 to 1.1. Furthermore, when component (D) is (D)(ii), the concentration of component (B′) is such that the ratio of the number of moles of silicon-bonded alkenyl groups in component (B′) to the sum of the number of moles of silicon-bonded hydrogen atoms in component (A′) and component (D)(ii) is typically from 0.4 to 2, alternatively from 0.8 to 1.5, alternatively from 0.9 to 1.1.

The mole ratio of silicon-bonded alkenyl groups or silicon-bonded hydrogen atoms in the silicone rubber (D) to silicon-bonded hydrogen atoms in the silicone resin (A′) is typically from 0.01 to 0.5, alternatively from 0.05 to 0.4, alternatively from 0.1 to 0.3.

According to a fifth embodiment, the hydrosilylation-curable silicone composition comprises (A″) a rubber-modified silicone resin prepared by reacting a silicone resin having the formula (R¹R²₂SiO_{1/2})_{w}(R²₂SiO_{2/2})ₓ(R¹SiO_{3/2})_{y}(SiO_{4/2})_{z} (I) and a silicone rubber having the formula R⁵R¹₂SiO(R¹R⁵SiO)_{c}SiR¹₂R⁵ (VI) in the presence of a hydrosilylation catalyst and, optionally, an organic solvent to form a soluble reaction product, wherein R¹ is C1 to C10 hydrocarbyl or C1 to C10 halogen-substituted hydrocarbyl, both free of aliphatic unsaturation, R² is R¹ or alkenyl, R⁵ is R¹ or —H, c has a value of from greater than 4 to 1,000, w is from 0 to 0.8, x is from 0 to 0.6, y is from 0 to 0.99, z is from 0 to 0.75, w+x+y+z=1, y+z/(w+x+y+z) is from 0.2 to 0.99, and w+x/(w+x+y+z) is from 0.01 to 0.8, provided the silicone resin (I) has an average of at least two silicon-bonded alkenyl groups per molecule, the silicone rubber (VI) has an average of at least two silicon-bonded hydrogen atoms per molecule, and the mole ratio of silicon-bonded hydrogen atoms in the silicone rubber (VI) to silicon-bonded alkenyl groups in silicone resin (I) is from 0.01 to 0.5; (B) an organosilicon compound having an average of at least two silicon-bonded hydrogen atoms per molecule in an amount sufficient to cure the rubber-modified silicone resin; and (C) a catalytic amount of a hydrosilylation catalyst.

Components (B) and (C) of the fifth embodiment of the silicone composition are as described and exemplified above for the first embodiment.

The concentration of component (B) is sufficient to cure (cross-link) the rubber-modified silicone resin. The concentration of component (B) is such that the ratio of the sum of the number of moles of silicon-bonded hydrogen atoms in component (B) and the silicone rubber (VI) to the number of moles of silicon-bonded alkenyl groups in the silicone resin (I) is typically from 0.4 to 2, alternatively from 0.8 to 1.5, alternatively from 0.9 to 1.1.

Component (A″) is a rubber-modified silicone resin prepared by reacting at least one silicone resin having the formula (R¹R²₂SiO_{1/2})_{w}(R²₂SiO_{2/2})ₓ(R¹SiO_{3/2})_{y}(SiO_{4/2})_{z} (I) and at least one silicone rubber having the formula R⁵R¹₂SiO(R¹R⁵SiO)_{c}SiR¹₂R⁵ (VI) in the presence of a hydrosilylation catalyst and, optionally, an organic solvent to form a soluble reaction product, wherein R¹, R², R⁵, w, x, y, z, y+z/(w+x+y+z), and w+x/(w+x+y+z) are as described and exemplified above, and the subscript c has a value of from greater than 4 to 1,000.

The silicone resin having the formula (I) is as described and exemplified above for the first embodiment of the silicone composition. Also, the hydrosilylation catalyst and organic solvent are as described and exemplified above in the method of preparing the organohydrogenpolysiloxane resin having the formula (II). As used herein the term “soluble reaction product” means when organic solvent is present, the product of the reaction for preparing component (A″) is miscible in the organic solvent and does not form a precipitate or suspension.

In the formula (VI) of the silicone rubber, R¹ and R⁵ are as described and exemplified above, and the subscript c typically has a value of from greater than 4 to 1,000, alternatively from 10 to 500, alternatively from 10 to 50.

Examples of silicone rubbers having the formula (VI) include, but are not limited to, silicone rubbers having the following formulae:

HMe₂SiO(Me₂SiO)₅₀SiMe₂H, HMe₂SiO(Me₂SiO)₁₀SiMe₂H, HMe₂SiO(PhMeSiO)₂₅SiMe₂H, and Me₃SiO(MeHSiO)₁₀SiMe₃, wherein Me is methyl, Ph is phenyl, and the numerical subscripts indicate the number of each type of siloxane unit.

The silicone rubber having the formula (VI) can be a single silicone rubber or a mixture comprising two or more different silicone rubbers, each having the formula (VI).

Methods of preparing silicone rubbers containing silicon-bonded hydrogen atoms are well known in the art; many of these compounds are commercially available.

The silicone resin (I), silicone rubber (VI), hydrosilylation catalyst, and organic solvent can be combined in any order. Typically, the silicone resin, silicone rubber, and organic solvent are combined before the introduction of the hydrosilylation catalyst.

The reaction is typically carried out at a temperature of from room temperature (˜23±2° C.) to 150° C., alternatively from room temperature to 100° C.

The reaction time depends on several factors, including the structures of the silicone resin and the silicone rubber, and the temperature. The components are typically allowed to react for a period of time sufficient to complete the hydrosilylation reaction. This means the components are typically allowed to react until at least 95 mol %, alternatively at least 98 mol %, alternatively at least 99 mol %, of the silicon-bonded hydrogen atoms originally present in the silicone rubber have been consumed in the hydrosilylation reaction, as determined by FTIR spectrometry. The time of reaction is typically from 0.5 to 24 h at a temperature of from room temperature (˜23±2° C.) to 100° C. The optimum reaction time can be determined by routine experimentation using the methods set forth in the Examples section below.

The mole ratio of silicon-bonded hydrogen atoms in the silicone rubber (VI) to silicon-bonded alkenyl groups in the silicone resin (I) is typically from 0.01 to 0.5, alternatively from 0.05 to 0.4, alternatively from 0.1 to 0.3.

The concentration of the hydrosilylation catalyst is sufficient to catalyze the addition reaction of the silicone resin (I) with the silicone rubber (VI). Typically, the concentration of the hydrosilylation catalyst is sufficient to provide from 0.1 to 1000 ppm of a platinum group metal, based on the combined weight of the resin and the rubber.

The concentration of the organic solvent is typically from 0 to 95% (w/w), alternatively from 10 to 75% (w/w), alternatively from 40 to 60% (w/w), based on the total weight of the reaction mixture.

The rubber-modified silicone resin can be used without isolation or purification in the fifth embodiment of the hydrosilylation-curable silicone composition or the resin can be separated from most of the solvent by conventional methods of evaporation. For example, the reaction mixture can be heated under reduced pressure. Moreover, when the hydrosilylation catalyst is a supported catalyst, described above, the rubber-modified silicone resin can be readily separated from the hydrosilylation catalyst by filtering the reaction mixture. However, when the rubber-modified silicone resin is not separated from the hydrosilylation catalyst used to prepare the resin, the catalyst may be used as component (C) of the fifth embodiment of the hydrosilylation-curable silicone composition.

According to a sixth embodiment, the hydrosilylation-curable silicone composition comprises (A′″) a rubber-modified silicone resin prepared by reacting a silicone resin having the formula (R¹R⁵₂SiO_{1/2})_{w}(R⁵₂SiO_{2/2})ₓ(R⁵SiO_{3/2})_{y}(SiO_{4/2})_{z} (III) and a silicone rubber having the formula R¹R²₂SiO(R²₂SiO)_{d}SiR²₂R¹ (VII) in the presence of a hydrosilylation catalyst and, optionally, an organic solvent to form a soluble reaction product, wherein R¹ is C1 to C10 hydrocarbyl or C1 to C10 halogen-substituted hydrocarbyl, both free of aliphatic unsaturation, R² is R¹ or alkenyl, R⁵ is R¹ or —H, subscript d has a value of from greater than 4 to 1,000, w is from 0 to 0.8, x is from 0 to 0.6, y is from 0 to 0.99, z is from 0 to 0.75, w+x+y+z=1, y+z/(w+x+y+z) is from 0.2 to 0.99, and w+x/(w+x+y+z) is from 0.01 to 0.8, provided the silicone resin (III) has an average of at least two silicon-bonded hydrogen atoms per molecule, the silicone rubber (VII) has an average of at least two silicon-bonded alkenyl groups per molecule, and the mole ratio of silicon-bonded alkenyl groups in the silicone rubber (VII) to silicon-bonded hydrogen atoms in the silicone resin (III) is from 0.01 to 0.5; (B′) an organosilicon compound having an average of at least two silicon-bonded alkenyl groups per molecule in an amount sufficient to cure the rubber-modified silicone resin; and (C) a catalytic amount of a hydrosilylation catalyst.

Components (B′) and (C) of the sixth embodiment of the silicone composition are as described and exemplified above for the second embodiment.

The concentration of component (B′) is sufficient to cure (cross-link) the rubber-modified silicone resin. The concentration of component (B′) is such that the ratio of the sum of the number of moles of silicon-bonded alkenyl groups in component (B′) and the silicone rubber (VII) to the number of moles of silicon-bonded hydrogen atoms in the silicone resin (III) is typically from 0.4 to 2, alternatively from 0.8 to 1.5, alternatively from 0.9 to 1.1.

Component (A′″) is a rubber-modified silicone resin prepared by reacting at least one silicone resin having the formula (R¹R⁵₂SiO_{1/2})_{w}(R⁵₂SiO_{2/2})ₓ(R⁵SiO_{3/2})_{y}(SiO_{4/2})_{z} (III) and at least one silicone rubber having the formula R¹R²₂SiO(R²₂SiO)_{d}SiR²₂R¹ (VII) in the presence of a hydrosilylation catalyst and an organic solvent to form a soluble reaction product, wherein R¹, R², R⁵, w, x, y, z, y+z/(w+x+y+z), and w+x/(w+x+y+z) are as described and exemplified above, and the subscript d has a value of from greater than 4 to 1,000.

The silicone resin having the formula (III) is as described and exemplified above for the second embodiment of the hydrosilylation-curable silicone composition. Also, the hydrosilylation catalyst and organic solvent are as described and exemplified above in the method of preparing the organohydrogenpolysiloxane resin having the formula (II). As in the previous embodiment of the silicone composition, the term “soluble reaction product” means when organic solvent is present, the product of the reaction for preparing component (A′″) is miscible in the organic solvent and does not form a precipitate or suspension.

In the formula (VII) of the silicone rubber, R¹ and R² are as described and exemplified above, and the subscript d typically has a value of from 4 to 1,000, alternatively from 10 to 500, alternatively form 10 to 50.

Examples of silicone rubbers having the formula (VII) include, but are not limited to silicone rubbers having the following formulae:

ViMe₂SiO(Me₂SiO)₅₀SiMe₂Vi, ViMe₂SiO(Me₂SiO)₁₀SiMe₂Vi, ViMe₂SiO(PhMeSiO)₂₅SiMe₂Vi, and Vi₂MeSiO(PhMeSiO)₂₅SiMe₂Vi, wherein Me is methyl, Ph is phenyl, Vi is vinyl, and the numerical subscripts indicate the number or each type of siloxane unit.

The silicone rubber having the formula (VII) can be a single silicone rubber or a mixture comprising two or more different silicone rubbers, each having the formula (VII).

Methods of preparing silicone rubbers containing silicon-bonded alkenyl groups are well known in the art; many of these compounds are commercially available.

The reaction for preparing component (A′″) can be carried out in the manner described above for preparing component (A″) of the fifth embodiment of the silicone composition, except the silicone resin having the formula (I) and the silicone rubber having the formula (VI) are replaced with the resin having the formula (III) and the rubber having the formula (VII), respectively. The mole ratio of silicon-bonded alkenyl groups in the silicone rubber (VII) to silicon-bonded hydrogen atoms in the silicone resin (III) is from 0.01 to 0.5, alternatively from 0.05 to 0.4, alternatively from 0.1 to 0.3. Moreover, the silicone resin and the silicone rubber are typically allowed to react for a period of time sufficient to complete the hydrosilylation reaction. This means the components are typically allowed to react until at least 95 mol %, alternatively at least 98 mol %, alternatively at least 99 mol %, of the silicon-bonded alkenyl groups originally present in the rubber have been consumed in the hydrosilylation reaction, as determined by FTIR spectrometry.

The hydrosilylation-curable silicone composition of the present method can comprise additional ingredients, provided the ingredient does not prevent the silicone composition from curing to form a cured silicone resin having low coefficient of thermal expansion, high tensile strength, and high modulus, as described below. Examples of additional ingredients include, but are not limited to, hydrosilylation catalyst inhibitors, such as 3-methyl-3-penten-1-yne, 3,5-dimethyl-3-hexen-1-yne, 3,5-dimethyl-1-hexyn-3-ol, 1-ethynyl-1-cyclohexanol, 2-phenyl-3-butyn-2-ol, vinylcyclosiloxanes, and triphenylphosphine; adhesion promoters, such as the adhesion promoters taught in U.S. Pat. Nos. 4,087,585 and 5,194,649; dyes; pigments; anti-oxidants; heat stabilizers; UV stabilizers; flame retardants; flow control additives; and diluents, such as organic solvents and reactive diluents.

For example, the hydrosilylation-curable silicone composition can contain (E) a reactive diluent comprising (i) an organosiloxane having an average of at least two silicon-bonded alkenyl groups per molecule and a viscosity of from 0.001 to 2 Pa·s at 25° C., wherein the viscosity of (E)(i) is not greater than 20% of the viscosity of the silicone resin, e.g., component (A), (A′), (A″), or (A′″) above, of the silicone composition and the organosiloxane has the formula (R¹R²₂SiO_{1/2})ₘ(R²₂SiO_{2/2})ₙ(R¹SiO_{3/2})ₚ(SiO_{4/2})_{q}, wherein R¹ is C1 to C10 hydrocarbyl or C1 to C10 halogen-substituted hydrocarbyl, both free of aliphatic unsaturation, R² is R¹ or alkenyl, m is 0 to 0.8, n=0 to 1, p=0 to 0.25, q=0 to 0.2, m+n+p+q=1, and m+n is not equal to 0, provided when p+q=0, n is not equal to 0 and the alkenyl groups are not all terminal, and (ii) an organohydrogensiloxane having an average of at least two silicon-bonded hydrogen atoms per molecule and a viscosity of from 0.001 to 2 Pa·s at 25° C., in an amount sufficient to provide from 0.5 to 3 moles of silicon-bonded hydrogen atoms in (E)(ii) per mole of alkenyl groups in (E)(i), wherein the organohydrogensiloxane has the formula (HR¹₂SiO_{1/2})ₛ(R¹SiO_{3/2})ₜ(SiO_{4/2})ᵥ, wherein R¹ is C1 to C10 hydrocarbyl or C1 to C10 halogen-substituted hydrocarbyl, both free of aliphatic unsaturation, s is from 0.25 to 0.8, t is from 0 to 0.5, v is from 0 to 0.3, s+t+v=1, and t+v is not equal to 0.

Component (E)(i) is at least one organosiloxane having an average of at least two alkenyl groups per molecule and a viscosity of from 0.001 to 2 Pa·s at 25° C., wherein the viscosity of (E)(i) is not greater than 20% of the viscosity of the silicone resin of the silicone composition and the organosiloxane has the formula (R¹R²₂SiO_{1/2})ₘ(R²₂SiO_{2/2})ₙ(R¹SiO_{3/2})ₚ(SiO_{4/2})_{q}, wherein R¹ is C1 to C10 hydrocarbyl or C1 to C10 halogen-substituted hydrocarbyl, both free of aliphatic unsaturation, R² is R¹ or alkenyl, m is 0 to 0.8, n=0 to 1, p=0 to 0.25, q=0 to 0.2, m+n+p+q=1, and m+n is not equal to 0, provided when p+q=0, n is not equal to 0 and the alkenyl groups are not all terminal (i.e., not all the alkenyl groups in the organosiloxane are in the R¹R²₂SiO_{1/2} units). Further, organosiloxane (E)(i) can have a linear, branched, or cyclic structure. For example, when the subscripts m, p, and q in the formula of organosiloxane (E)(i) are each equal to 0, the organosiloxane is an organocyclosiloxane.

The viscosity of organosiloxane (E)(i) at 25° C. is typically from 0.001 to 2 Pa·s, alternatively from 0.001 to 0.1 Pa·s, alternatively from 0.001 to 0.05 Pa·s. Further, the viscosity of organosiloxane (E)(i) at 25° C. is typically not greater than 20%, alternatively not greater than 10%, alternatively not greater than 1%, of the viscosity of the silicone resin in the hydrosilylat on-curable silicone composition.

Examples of organosiloxanes suitable for use as organosiloxane (E)(i) include, but are not limited to, organosiloxanes having the following formulae:

(ViMeSiO)₃, (ViMeSiO)₄, (ViMeSiO)₅, (ViMeSiO)₆, (ViPhSiO)₃, (ViPhSiO)₄, (ViPhSiO)₅, (ViPhSiO)₆, ViMe₂SiO(ViMeSiO)ₙSiMe₂Vi, Me₃SiO(ViMeSiO)ₙSiMe₃, and (ViMe₂SiO)₄Si, where Me is methyl, Ph is phenyl, Vi is vinyl, and the subscript n has a value such that the organosiloxane has a viscosity of from 0.001 to 2 Pa·s at 25° C.

Component (E)(i) can be a single organosiloxane or a mixture comprising two or more different organosiloxanes, each as described above. Methods of making alkenyl-functional organosiloxanes are well known in the art.

Component (E)(ii) is at least one organohydrogensiloxane having an average of at least two silicon-bonded hydrogen atoms per molecule and a viscosity of from 0.001 to 2 Pa·s at 25° C., in an amount sufficient to provide from 0.5 to 3 moles of silicon-bonded hydrogen atoms in (E)(ii) to moles of alkenyl groups in (E)(i), wherein the organohydrogensiloxane has the formula (HR¹₂SiO_{1/2})ₛ(R¹SiO_{3/2})ₜ(SiO_{4/2})ᵥ, wherein R¹ is C1 to C10 hydrocarbyl or C1 to C10 halogen-substituted hydrocarbyl, both free of aliphatic unsaturation, s is from 0.25 to 0.8, t is from 0 to 0.5, v is from 0 to 0.3, s+t+v=1, and t+v is not equal to 0.

The viscosity of organohydrogensiloxane (E)(ii) at 25° C. is typically from 0.001 to 2 Pa·s, alternatively from 0.001 to 0.1 Pa·s, alternatively from 0.001 to 0.05 Pa·s.

Examples of organohydrogensiloxanes suitable for use as organohydrogensiloxane (E)(ii) include, but are not limited to, organohydrogensiloxanes having the following formulae:

PhSi(OSiMe₂H)₃, Si(OSiMe₂H)₄, MeSi(OSiMe₂H)₃, (HMe₂SiO)₃SiOSi(OSiMe₂H)₃, and (HMe₂SiO)₃SiOSi(Ph)(OSiMe₂H)₂, where Me is methyl and Ph is phenyl.

Component (E)(ii) can be a single organohydrogensiloxane or a mixture comprising two or more different organohydrogensiloxanes, each as described above. Methods of making organohydrogensiloxanes are well known in the art.

The concentration of component (E)(ii) is sufficient to provide from 0.5 to 3 moles of silicon-bonded hydrogen atoms, alternatively from 0.6 to 2 moles of silicon-bonded hydrogen atoms, alternatively from 0.9 to 1.5 moles of silicon-bonded hydrogen atoms, per mole of alkenyl groups in component (E)(i).

The concentration of the reactive diluent (E), component (E)(i) and (E)(ii) combined, in the hydrosilylation-curable silicone composition is typically from 0 to 90% (w/w), alternatively from 0 to 50% (w/w), alternatively from 0 to 20% (w/w), alternatively from 0 to 10% (w/w), based on the combined weight of the silicone resin, component (A), (A′), (A″), or (A′″), and the organosilicon compound, component (B) or (B′) in the embodiments above.

The silicone composition can be a one-part composition comprising the silicone resin, organosilicon compound, and hydrosilylation catalyst in a single part or, alternatively, a multi-part composition comprising these components in two or more parts. For example, a multi-part silicone composition can comprise a first part containing a portion of the silicone resin and all of the hydrosilylation catalyst, and a second part containing the remaining portion of the silicone resin and all of the organosilicon compound.

The one-part silicone composition is typically prepared by combining the principal components and any optional ingredients in the stated proportions at ambient temperature, with or without the aid of an organic solvent. Although the order of addition of the various components is not critical if the silicone composition is to be used immediately, the hydrosilylation catalyst is preferably added last at a temperature below about 30° C. to prevent premature curing of the composition. Also, the multi-part silicone composition can be prepared by combining the components in each part.

Mixing can be accomplished by any of the techniques known in the art such as milling, blending, and stirring, either in a batch or continuous process. The particular device is determined by the viscosity of the components and the viscosity of the final silicone composition.

As an alternative to the hydrosilylation-curable silicone composition, condensation-curable silicone compositions are also suitable for the silicone composition of the present invention.

The condensation-curable silicone composition typically includes a silicone resin (A″″) having silicon-bonded hydroxy or hydrolysable groups and, optionally, a cross-linking agent (B″) having silicon-bonded hydrolysable groups and/or a condensation catalyst (C′). The silicone resin (A″″) is typically a copolymer containing T and/or Q siloxane units in combination with M and/or D siloxane units.

According to one embodiment, the silicone resin (A″″) has the formula:

(R¹R⁶₂SiO_{1/2})_{w′}(R⁶₂SiO_{2/2})_{x′}(R⁶SiO_{3/2})_{y′}(SiO_{4/2})_{z′} (VIII)

wherein R¹ is as defined and exemplified above, R⁶ is R¹, —H, —OH, or a hydrolysable group, and w′ is from 0 to 0.8, preferably from 0.02 to 0.75, and more preferably from 0.05 to 0.3, x′ is from 0 to 0.95, preferably from 0.05 to 0.8, and more preferably from 0.1 to 0.3, y′ is from 0 to 1, preferably from 0.25 to 0.8, and more preferably from 0.5 to 0.8, and z′ is from 0 to 0.99, preferably from 0.2 to 0.8, and more preferably from 0.4 to 0.6, and the silicone resin (A″″) has an average of at least two silicon-bonded hydrogen atoms, hydroxy groups, or hydrolysable groups per molecule. As used herein the term “hydrolysable group” means the silicon-bonded group reacts with water in the absence of a catalyst at any temperature from room temperature (˜23±2° C.) to 100° C. within several minutes, for example thirty minutes, to form a silanol (Si—OH) group. Examples of hydrolysable groups represented by R⁶ include, but are not limited to, —Cl, —Br, —OR₇, —OCH₂CH₂OR⁷, CH₃C(═O)O—, Et(Me)C═N—O—, CH₃C(═O)N(CH₃)—, and —ONH₂, wherein R⁷ is C1 to C8 hydrocarbyl or C1 to C8 halogen-substituted hydrocarbyl.

The hydrocarbyl and halogen-substituted hydrocarbyl groups represented by R⁷ typically have from 1 to 8 carbon atoms, alternatively from 3 to 6 carbon atoms. Acyclic hydrocarbyl and halogen-substituted hydrocarbyl groups containing at least 3 carbon atoms can have a branched or unbranched structure. Examples of hydrocarbyl groups represented by R⁷ include, but are not limited to, unbranched and branched alkyl, such as methyl, ethyl, propyl, 1-methylethyl, butyl, 1-methylpropyl, 2-methylpropyl, 1,1-dimethylethyl, pentyl, 1-methylbutyl, 1-ethylpropyl, 2-methylbutyl, 3-methylbutyl, 1,2-dimethylpropyl, 2,2-dimethylpropyl, hexyl, heptyl, and octyl; cycloalkyl, such as cyclopentyl, cyclohexyl, and methylcyclohexyl; phenyl; alkaryl, such as tolyl and xylyl; aralkyl, such as benzyl and phenethyl; alkenyl, such as vinyl, allyl, and propenyl; arylalkenyl, such as styryl; and alkynyl, such as ethynyl and propynyl. Examples of halogen-substituted hydrocarbyl groups represented by R⁷ include, but are not limited to, 3,3,3-trifluoropropyl, 3-chloropropyl, chlorophenyl, and dichlorophenyl.

Typically, at least 5 mol %, alternatively at least 15 mol %, alternatively at least 30 mol % of the groups R⁶ in the silicone resin are hydrogen, hydroxy, or a hydrolysable group. As used herein, the mol % of groups in R⁶ is defined as a ratio of the number of moles of silicon-bonded groups in the silicone resin (A″″) to the total number of moles of the R⁶ groups in the silicone resin (A″″), multiplied by 100.

Specific examples of silicone resins (A″″) include, but are not limited to, silicone resins having the following formulae:

(MeSiO_{3/2})ₙ, (PhSiO_{3/2})n, (Me₃SiO_{1/2})_{0.8}(SiO_{4/2})_{0.2}, (MeSiO_{3/2})_{0.67}(PhSiO_{3/2})_{0.33}, (MeSiO_{3/2})_{0.45}(PhSiO_{3/2})_{0.40}(Ph₂SiO_{2/2})_{0.1}(PhMeSiO_{2/2})_{0.05}, (PhSiO_{3/2})_{0.4}(MeSiO_{3/2})_{0.45}(PhSiO_{3/2})_{0.1}(PhMeSiO_{2/2})_{0.05}, and (PhSiO_{3/2})_{0.4}(MeSiO_{3/2})_{0.1}(PhMeSiO_{2/2})_{0.5},

wherein Me is methyl, Ph is phenyl, the numerical subscripts outside the parenthesis denote mole fractions, and the subscript n has a value such that the silicone resin has a number-average molecular weight of from 500 to 50,000. The sequence of units in the preceding formulae is not to be viewed in any way as limiting to the scope of the invention. These formulae represent the fully condensed forms of the resins. Before curing they will have —H, —OH, and/or other hydrolysable groups in the amount specified above.

As set forth above, the silicone resin (A″″) represented by formula (VIII) typically has a number-average molecular weight (Mn) of from 500 to 50,000. Alternatively, the silicone resin (A″″) may have a Mn of from 300 to non-measurable, alternatively 1,000 to 3,000, where the molecular weight is determined by gel permeation chromatography employing a low angle laser light scattering detector, or a refractive index detector and silicone resin (MQ) standards.

The viscosity of the silicone resin (A″″) at 25° C. is typically from 0.01 Pa·s to a solid, alternatively from 0.1 to 100,000 Pa·s, alternatively from 1 to 1,000 Pa·s.

Methods of preparing silicone resins (A″″) represented by formula (VIII) are well known in the art; many of these resins are commercially available. Silicone resins (A″″) represented by formula (VIII) are typically prepared by cohydrolyzing the appropriate mixture of chlorosilane precursors in an organic solvent, such as toluene. For example, a silicone resin including R¹R⁶₂SiO_{1/2} units and R⁶SiO_{3/2} units can be prepared by cohydrolyzing a first compound having the formula R¹R⁶₂SiCl and a second compound having the formula R⁶SiCl₃ in toluene, where R¹ and R⁶ are as defined and exemplified above. The cohydrolyzing process is described above in terms of the hydrosilylation-curable silicone composition. The cohydrolyzed reactants can be further “bodied” to a desired extent to control the amount of crosslinkable groups and viscosity.

The Q units in formula (VIII) and their combination in any ratio with the M units can also be in the form of discrete particles in the resin (A″″). The particle size is typically from 1 nm to 20 μm. Examples of these particles include, but not limited to, silica (SiO_{4/2}) particles of 15 nm in diameter. The condensation curable silicone resin can further contain inorganic fillers such as silica, alumina, calcium carbonate, and mica.

In another embodiment, the condensation-curable silicone composition comprises a rubber-modified silicone resin (A″″) prepared by reacting an organosilicon compound selected from (i) a silicone resin having the formula (R¹R⁶₂SiO_{1/2})_{w}(R⁶₂SiO_{2/2})ₓ(R⁶SiO_{3/2})_{y}(SiO_{4/2})_{z} and (ii) hydrolysable precursors of (i), and (iii) a silicone rubber having the formula R⁸₃SiO(R¹R⁸SiO)ₘSiR⁸₃ in the presence of water, (iv) a condensation catalyst, and (v) an organic solvent, wherein R¹ and R⁶ are as defined and exemplified above, R⁸ is R¹ or a hydrolysable group, m is from 2 to 1,000, alternatively from 4 to 500, alternatively from 8 to 400, and w, x, y, and z are as defined and exemplified above, and silicone resin (i) has an average of at least two silicon-bonded hydroxy or hydrolysable groups per molecule, the silicone rubber (iii) has an average of at least two silicon-bonded hydrolysable groups per molecule, and the mole ratio of silicon-bonded hydrolysable groups in the silicone rubber (iii) to silicon-bonded hydroxy or hydrolysable groups in the silicone resin (i) is from 0.01 to 1.5, alternatively from 0.05 to 0.8, alternatively from 0.2 to 0.5.

Typically at least 5 mol %, alternatively at least 15 mol %, alternatively at least 30 mol % of the groups R⁶ in the silicone resin (i) are hydroxy or hydrolysable groups.

The silicone resin (i) typically has a number-average molecular weight (Mn) of from 300 to non-measurable, alternatively from 500 to 10,000, alternatively 1,000 to 3,000, where the molecular weight is determined by gel permeation chromatography employing a low angle laser light scattering detector, or a refractive index detector and silicone resin (MQ) standards.

Specific examples of silicone resins suitable for use as silicone resin (i) include, but are not limited to, resins having the following formulae:

(MeSiO_{3/2})ₙ, (PhSiO_{3/2})ₙ, (PhSiO_{3/2})_{0.4}(MeSiO_{3/2})_{0.45}(PhSiO_{3/2})_{0.1}(PhMeSiO_{2/2})_{0.05}, and (PhSiO_{3/2})_{0.3}(SiO_{4/2})_{0.1}(Me₂SiO_{2/2})_{0.2}(Ph₂SiO_{2/2})_{0.4}, where Me is methyl, Ph is phenyl, the numerical subscripts outside the parenthesis denote mole fractions, and the subscript n has a value such that the silicone resin has a number-average molecular weight of from 500 to 50,000. The sequence of units in the preceding formulae is not to be viewed in any way as limiting to the scope of the invention. Silicone resin (i) can be a single silicone resin or a mixture comprising two or more different silicone resins, each having the specified formula.

These formulae represent the fully condensed forms of the resins. Before curing they will have —H, —OH, and/or other hydrolysable groups in the amount specified above.

As used herein, the term “hydrolysable precursors” refers to silanes having hydrolysable groups that are suitable for use as starting materials (precursors) for preparation of the silicone resin (i). The hydrolysable precursors (ii) can be represented by the formulae R¹R⁸₂SiX, R⁸₂SiX₂, R⁸SiX₃, and SiX₄, wherein R¹, R⁸, and X are as defined and exemplified above.

Specific examples of hydrolysable precursors (ii) include, but are not limited to, silanes having the formulae:

Me₂ViSiCl, Me₃SiCl, MeSi(OEt)₃, PhSiCl₃, MeSiCl₃, Me₂SiCl₂, PhMeSiCl₂, SiCl₄, Ph₂SiCl₂, PhSi(OMe)₃, MeSi(OMe)₃, PhMeSi(OMe)₂, and Si(OEt)₄,

wherein Me is methyl, Et is ethyl, and Ph is phenyl.

Specific examples of silicone rubbers (iii) include, but are not limited to, silicone rubbers having the following formulae:

(EtO)₃SiO(Me₂SiO)₅₅Si(OEt)₃, (EtO)₃SiO(Me₂SiO)₁₆Si(OEt)₃, (EtO)₃SiO(Me₂SiO)₃₈₆Si(OEt)₃, and (EtO)₂MeSiO(PhMeSiO)₁₀SiMe(OEt)₂,

wherein Me is methyl and Et is ethyl.

The reaction is typically carried out at a temperature of from room temperature (˜23±2° C.) to 180° C., alternatively from room temperature to 100° C.

The reaction time depends on several factors, including the structures of the silicone resin (i) and the silicone rubber (iii), and the temperature. The components are typically allowed to react for a period of time sufficient to complete the condensation reaction. This means the components are allowed to react until at least 95 mol %, alternatively at least 98 mol %, alternatively at least 99 mol %, of the silicon-bonded hydrolysable groups originally present in the silicone rubber (iii) have been consumed in the condensation reaction, as determined by ²⁹Si NMR spectrometry. The time of reaction is typically from 1 to 30 h at a temperature of from room temperature (˜23±2° C.) to 100° C. The optimum reaction time can be determined by routine experimentation.

Suitable condensation catalysts (iv) are described in further detail below, and suitable organic solvents (v) are described above in the context of rubber-modified silicone resin (A′) above. The concentration of the condensation catalyst (iv) is sufficient to catalyze the condensation reaction of the silicone resin (i) with the silicone rubber (iii). Typically, the concentration of the condensation catalyst (iv) is from 0.01 to 2% (w/w), alternatively from 0.01 to 1% (w/w), alternatively from 0.05 to 0.2% (w/w), based on the weight of the silicon resin (i). The concentration of the organic solvent (v) is typically from 10 to 95% (w/w), alternatively from 20 to 85% (w/w), alternatively from 50 to 80% (w/w), based on the total weight of the reaction mixture.

The concentration of water in the reaction mixture depends on the nature of the groups R8 in the organosilicon compound and the nature of the silicon-bonded hydrolysable groups in the silicone rubber. When the silicone resin (i) contains hydrolysable groups, the concentration of water is sufficient to effect hydrolysis of the hydrolysable groups in the silicon resin (i) and the silicone rubber (iii). For example, the concentration of water is typically from 0.01 to 3 moles, alternatively from 0.05 to 1 moles, per mole of hydrolysable group in the silicone resin (i) and the silicone rubber (iii) combined. When the silicone resin (i) does not contain hydrolysable groups, only a trace amount, e.g., 100 ppm, of water is required in the reaction mixture. Trace amounts of water are normally present in the reactants and/or solvent.

As set forth above, the condensation-curable silicone composition can further comprise the cross-linking agent (B″). The cross-linking agent (B″) can have the formula R⁷_{q}SiX_{4-q}, wherein R⁷ is C1 to C8 hydrocarbyl or C1 to C8 halogen-substituted hydrocarbyl, X is a hydrolysable group, and q is 0 or 1. The hydrocarbyl and halogen-substituted hydrocarbyl groups represented by R⁷, and the hydrolysable groups represented by X are as described and exemplified above.

Specific examples of cross-linking agents (B″) include, but are not limited to, alkoxy silanes such as MeSi(OCH₃)₃, CH₃Si(OCH₂CH₃)₃, CH₃Si(OCH₂CH₂CH₃)₃, CH₃Si[O(CH₂)₃CH₃]₃, CH₃CH₂Si(OCH₂CH₃)₃, C₆H₅Si(OCH₃)₃, C₆H₅CH₂Si(OCH₃)₃, C₆H₅Si(OCH₂CH₃)₃, CH₂═CHSi(OCH₃)₃, CH₂═CHCH₂Si(OCH₃)₃, CF₃CH₂CH₂Si(OCH₃)₃, CH₃Si(OCH₂CH₂OCH₃)₃, CF₃CH₂CH₂Si(OCH₂CH₂OCH₃)₃, CH₂═CHSi(OCH₂CH₂OCH₃)₃, CH₂═CHCH₂Si(OCH₂CH₂OCH₃)₃, C₆H₅Si(OCH₂CH₂OCH₃)₃, Si(OCH₃)₄, Si(OC₂H₅)₄, and Si(OC₃H₇)₄; organoacetoxysilanes such as CH₃Si(OCOCH₃)₃, CH₃CH₂Si(OCOCH₃)₃, and CH₂═CHSi(OCOCH₃)₃; organoiminooxysilanes such as CH₃Si[O—N═C(CH₃)CH₂CH₃]₃, Si[O—N═C(CH₃)CH₂CH₃]₄, and CH₂═CHSi[O—N═C(CH₃)CH₂CH₃]₃; organoacetamidosilanes such as CH₃Si[NHC(═O)CH₃]₃ and C₆H₅Si[NHC(═O)CH₃]₃; amino silanes such as CH₃Si[NH(s-C₄H₉)]₃ and CH₃Si(NHC₆H₁₁)₃; and organoaminooxysilanes.

The cross-linking agent (B″) can be a single silane or a mixture of two or more different silanes, each as described above. Also, methods of preparing tri- and tetra-functional silanes are well known in the art; many of these silanes are commercially available.

When present, the concentration of the cross-linking agent (B″) in the condensation-curable silicone composition is sufficient to cure (cross-link) the condensation-curable silicone resin. The exact amount of the cross-linking agent (B″) depends on the desired extent of cure, which generally increases as the ratio of the number of moles of silicon-bonded hydrolysable groups in the cross-linking agent (B″) to the number of moles of silicon-bonded hydrogen atoms, hydroxy groups, or hydrolysable groups in the silicone resin (A″″) increases. Typically, the concentration of the cross-linking agent (B″) is sufficient to provide from 0.2 to 4 moles of silicon-bonded hydrolysable groups per mole of silicon-bonded hydrogen atoms, hydroxy groups, or hydrolysable groups in the silicone resin (A″″). The optimum amount of the cross-linking agent (B′) can be readily determined by routine experimentation.

Condensation catalyst (C′) can be any condensation catalyst typically used to promote condensation of silicon-bonded hydroxy (silanol) groups to form Si—O—Si linkages. Examples of condensation catalysts include, but are not limited to, amines; and complexes of lead, tin, zinc, and iron with carboxylic acids. In particular, the condensation catalyst (C′) can be selected from tin(II) and tin(IV) compounds such as tin dilaurate, tin dioctoate, and tetrabutyl tin; and titanium compounds such as titanium tetrabutoxide.

When present, the concentration of the condensation catalyst (C′) is typically from 0.1 to 10% (w/w), alternatively from 0.5 to 5% (w/w), alternatively from 1 to 3% (w/w), based on the total weight of the silicone resin (A″″).

When the condensation-curable silicone composition includes the condensation catalyst (C′), the condensation-curable silicone composition is typically a two-part composition where the silicone resin (A″″) and condensation catalyst (C′) are in separate parts.

The condensation-curable silicone composition of the present invention can comprise additional ingredients, as known in the art and as described above for the hydrosilylation-curable silicone composition.

Referring now to FIG. 1B, a fibrous material 120 may be placed in or on the layer of curable silicon-containing composition 115. As shown in the inset 125, the fibrous material 120 may include individual fibers 130 separated by openings 135. Accordingly, the fibers 130 may be in, on, or above the layer of curable silicon-containing composition 115 and the openings 135 may or may not be impregnated by portions of the film of curable silicon-containing composition 115. In one embodiment, the fibrous material 120 is a glass fabric. For example, a Style 106 glass fabric piece, measuring 8″×8″, supplied by BGF Industries may be placed in or on the film of curable silicon-containing composition 115. However, persons of ordinary skill in the art should appreciate that the present invention is not limited to the glass fabric.

In alternative embodiments, the fibrous material 120 can be any material comprising fibers 125, provided the material has a high modulus and high tensile strength. For example, the fibrous material 120 may have a Young's modulus at 25° C. of at least 3 GPa. For example, the fibrous material 120 may have a Young's modulus at 25° C. of from 3 to 1,000 GPa, alternatively from 3 to 200 GPa, alternatively from 10 to 100 GPa. Moreover, the fibrous material 120 may have a tensile strength at 25° C. of at least 50 MPa. For example, the fibrous material 120 may have a tensile strength at 25° C. of from 50 to 10,000 MPa, alternatively from 50 to 1,000 MPa, alternatively from 50 to 500 MPa.

The fibrous material 120 can be a woven fabric, e.g., a cloth; a nonwoven fabric, e.g., a mat or roving; or loose (individual) fibers. The fibers in the fibrous material 120 are typically cylindrical in shape and have a diameter of from 1 to 100 μm, alternatively from 1 to 20 μm, alternatively from 1 to 10 μm. Loose fibers may be continuous, meaning the fibers extend throughout the reinforced silicone resin film in a generally unbroken manner, or chopped. The fibrous material 120 may be heat-treated prior to use to remove organic contaminants. For example, the fibrous material 120 may be heated in air at an elevated temperature, for example, 575° C., for a suitable period of time, for example 2 h. Examples of fibrous material 120 include, but are not limited to reinforcements comprising glass fibers; quartz fibers; graphite fibers; nylon fibers; polyester fibers; aramid fibers, such as Kevlar® and Nomex®; polyethylene fibers; polypropylene fibers; and silicon carbide fibers.

The fibrous material 120 can be embedded in the layer of curable silicon-containing composition 115 by simply placing the fibrous material 120 on the layer of curable silicon-containing composition 115 and allowing the silicone composition of the layer of curable silicon-containing composition 115 to saturate the fibrous material 120. In one embodiment, the embedded fibrous material 120 is degassed. The embedded fibrous material 120 can be degassed by subjecting it to a vacuum at a temperature of from room temperature (˜23±2° C.) to 60° C., for a period of time sufficient to remove entrapped air in the embedded reinforcement. For example, the embedded fibrous material 120 can typically be degassed by subjecting it to a pressure of from 1,000 to 20,000 Pa for 5 to 60 min. at room temperature.

Referring now to FIG. 1C, a layer of curable silicon-containing composition 145 may then be applied to the layer 115 and the impregnated fibrous material 120. The layer 145 may be applied using the conventional techniques described above. The layer 115, the impregnated fibrous material 120, and the layer 145 may be referred to collectively as a reinforced silicone resin film 150. In one embodiment, the reinforced silicone resin film 150 may be compressed to remove excess silicone composition and/or entrapped air, and to reduce the thickness of the reinforced silicone resin film 150. The reinforced silicone resin film 150 can be compressed using conventional equipment such as a stainless steel roller, hydraulic press, rubber roller, or laminating roll set. The reinforced silicone resin film 150 is typically compressed at a pressure of from 1,000 Pa to 10 MPa and at a temperature of from room temperature (˜23±2° C.) to 50° C. In one embodiment, the reinforced silicone resin film 150 may then be cured or partially cured using any of the techniques described above.

In the illustrated embodiment, the reinforced silicone resin film 150 is coated with a scratch resistant coating 155. For example, the reinforced silicone resin film 150 may be coated with a solution in isopropanol of a resin with a formula (MeSiO_{3/2})(SiO₂). However, persons of ordinary skill in the art having benefit of the present disclosure should appreciate that the particular scratch resistant coating 155 is a matter of design choice and not material to the present invention. In alternative embodiments, other scratch resistant coatings 155, or combinations of coatings, may be used to code the reinforced silicone resin film 150. Persons of ordinary skill in the art should also appreciate that the scratch resistant coating 155 is optional and not required for the practice of the present invention. Accordingly, in some embodiments, no scratch resistant coatings 155 may be applied to the silicone resin film 150.

Two reinforced silicone resin films, such as the silicone resin film 150 described above, both prepared from the Dow Corning 0-3015 resin and glass fabric but one with and the other without being coated with a scratch resistant coating 155, were gradually heated in a vacuum chamber at a rate of about 5-10° C. per minute. The starting pressure of the test was approximately 10⁻⁶ Torr. During the test, the pressure was recorded as the function of the substrate temperature. For the reinforced silicone resin film that included a scratch resistant coating, a maximum pressure of 5.2×10⁻⁶ Torr was reached at 280° C. The pressure dropped as the temperature was raised further. With the uncoated reinforced silicone resin film, a maximum pressure of 13×10-6 Torr was reached at 150° C. Again the pressure dropped as the temperature was further raised. These show that outgassing from reinforced silicone resin films is lower than many organic polymer based films and are suitable for amorphous silicon based photovoltaic. For example, conventional organic polymer-based films exhibit maximum pressures that may be as much as or more than two orders of magnitude larger than the maximum pressures reached by the reinforced silicone resin films described above.

A photovoltaic element 160 may be formed adjacent the reinforced silicone resin film 150 or, if present, the scratch resistant coating 155. In accordance with common usage in the art, the term “adjacent” will be understood to mean that a first layer may be formed immediately adjacent to a second layer. The term “adjacent” may also indicate that the first layer is formed near the second layer, although there may be one or more intervening layers between the first and second layers. In the illustrated embodiment, the photovoltaic element 160 is formed above the reinforced silicone resin film 150 and, if present, the scratch resistant coating 155. Accordingly, the reinforced silicone resin film 150 may act as a substrate for the photovoltaic element 160. However, persons of ordinary skill in the art having benefit of the present disclosure should appreciate that the reinforced silicone resin film 150 is not limited to acting as a substrate. In alternative embodiments, the reinforced silicone resin film 150 may be a superstrate for the photovoltaic element 160.

The photovoltaic element 160 may include one or more layers as shown in FIG. 1E. In the illustrated embodiment, a molybdenum layer 165 is formed adjacent the scratch resistant coating 155 and a reflective layer 170 is formed adjacent the molybdenum layer 165. For example, the reflective layer 170 may be formed of zinc oxide and/or aluminum. The layers 165, 170 may be formed using conventional techniques known to persons of ordinary skill in the art. For example, solar cells may be fabricated by sputtering a layer of molybdenum (Mo) on the scratch resistant coating 155 coated reinforced silicone resin film 150. The reflective layer 170 of ZnO/Al may then be RF sputtered on Mo. In one embodiment, Al is sputtered at 250° C., at the power of 100 W, and with an Ar flow rate of 30 sccm and a pressure of 4.5 mTorr. In this embodiment, sputtering settings for ZnO are 250° C., 100 W in power, an Ar flow rate of 4 sccm and a pressure of 4 mTorr. The resulting film thicknesses are about 100 nm of Al and about 500 nm of ZnO.

A photo-reactive layer 175 may then be formed above the reflective layer 170 and a contact layer 180 may be formed above the photo-reactive layer 175. The photo-reactive layer of 175 and the contact layer 180 may be formed using techniques known to persons of ordinary skill in the art. For example, the photo-reactive layer 175 may comprise an intermediate band gap n-i-p a-SiGe:H solar cells that can be deposited by radiofrequency, plasma-enhanced chemical vapor deposition (RF-PECVD). In the illustrated embodiment, the cell stack 175 is about 3 microns thick. An indium tin oxide (ITO) top contact 180 may then be applied by radiofrequency (RF) sputtering and light-assisted electrochemical shunt passivation may be performed. In one embodiment, the ITO contact 180 may be etched to produce smaller cells for measurement and yield evaluation.

The completed solar cell 185 including the photovoltaic element 160 and the reinforced silicone resin film 150 may then be removed from the substrate and, if present the release layer, as shown in FIG. 1F. It is also to be appreciated by those skilled in the art that the substrate layer 105 does not necessarily have to be present during the solar cell fabrication process. The reinforced silicone resin film can be released from 105 and becomes freestanding. Then the solar cell stack can be fabricated on the freestanding reinforced silicone resin film. In this case no step is needed to release from 105. The properties of the solar cell 185 may be determined using various measurements. For example, in one embodiment, the I-V parameters of a small area cell were measured. The results were: V_{oc}=0.49V, J_{sc}=15.6 mA/cm² (from quantum efficiency measurement), FF=0.49 and efficiency=3.7% under AM1.5G illumination. In another embodiment, amorphous silicon solar cells formed on a continuous roll of glass fabric reinforced 0-3015 resin described earlier produced ˜1% efficiency. Other amorphous silicon solar cells formed on the same substrate achieved an efficiency of 3.7%.

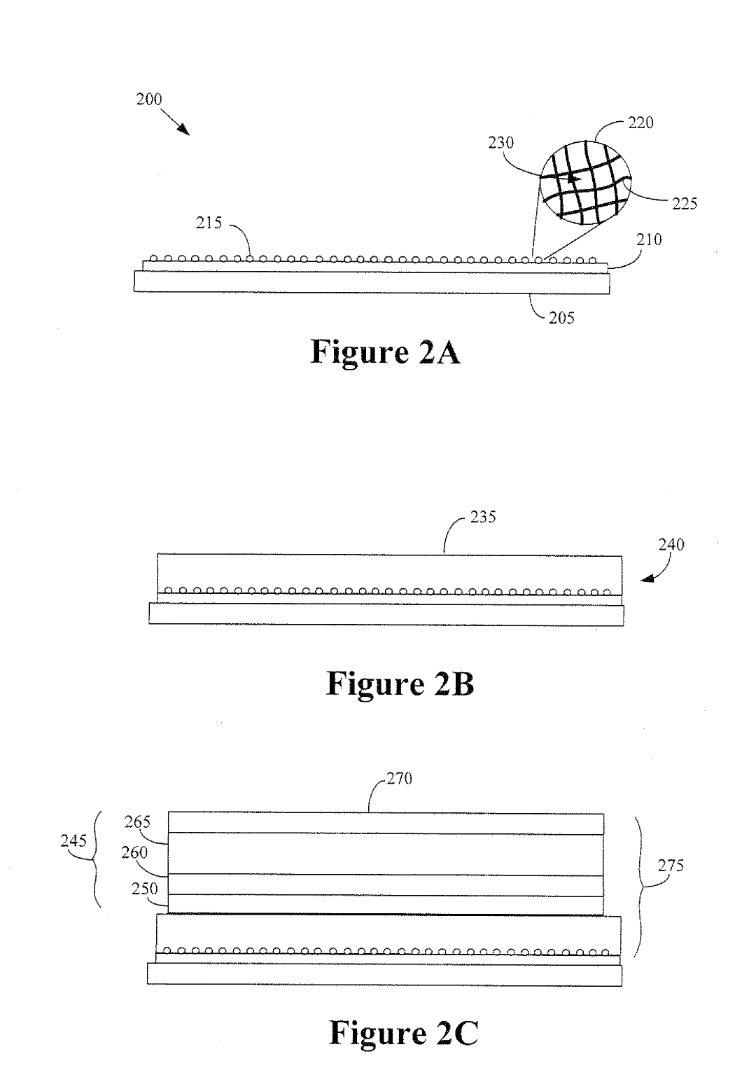

FIGS. 2A, 2B, and 2C conceptually illustrate a second exemplary embodiment of a method 200 of forming a solar cell. In the illustrated embodiment, a substrate 205 is treated to form a release layer 210 that is intended to decreased adherence of subsequently formed layers to the substrate 205 and to allow the subsequently formed layers to be released from the substrate 205. The release layer 210 can be any rigid or flexible material having a surface from which the reinforced silicone resin film can be removed without damage by delamination after the silicone resin is cured, as described below. Examples of release liners include, but are not limited to, Nylon, polyethyleneterephthalate, polyimide, PTFE, and sol gel coatings. For example, the substrate 205 may be a glass plate having dimensions of 6″×6″ that is treated with Relisse® 2520, from Nanofilm, Inc of Valley View, Ohio to form the release layer 210. However, persons of ordinary skill in the art having benefit of the present disclosure should appreciate that any material may be used to form the substrate 205 and/or the release layer 210. Furthermore, the release layer 210 is optional and not necessary for the practice of the present invention.

A fibrous material 215 may be placed in or on the substrate 205 or, if present, the release layer 210, as shown in FIG. 2A. As shown in the inset 220, the fibrous material 215 may include individual fibers 225 separated by openings 230. Accordingly, the fibers 225 may be in, on, or above the substrate 205 or, if present, the release layer 210. In one embodiment, the fibrous material 215 is a glass fabric. For example, a Style 106 glass fabric piece, measuring 8″×8″, supplied by BGF Industries may be placed in or on the substrate and 205 or, if present, the release layer 210. However, persons of ordinary skill in the art should appreciate that the present invention is not limited to the glass fabric. In alternative embodiments, the fibrous material 215 can be any material comprising fibers 225. Examples of alternative fibrous materials 215 are discussed in detail above.

Referring now to FIG. 2B, a layer of curable silicon-containing composition 235 may then be applied in, on, or above the substrate 205, the release layer 210 (if present), and the fibrous material 215. The layer 235 may be applied using the conventional techniques described above. In one embodiment, the reinforced silicone resin film 240 may be compressed to remove excess silicone composition and/or entrapped air, and to reduce the thickness of the reinforced silicone resin film 240. The reinforced silicone resin film 240 can be compressed using conventional equipment such as a stainless steel roller, hydraulic press, rubber roller, or laminating roll set. The reinforced silicone resin film 240 is typically compressed at a pressure of from 1,000 Pa to 10 MPa and at a temperature of from room temperature (˜23±2° C.) to 50° C. In one embodiment, the reinforced silicone resin film 240 may then be cured or partially cured using any of the techniques described above. Although not shown in the illustrated embodiment, the reinforced silicone resin film 240 may be coated with a scratch resistant coating, as discussed above. The layer 235, the fibrous material 215, and the scratch resistant coating (if present) may be referred to collectively as a reinforced silicone resin film 240.

A photovoltaic element 245 may be formed adjacent the reinforced silicone resin film 240, as shown in FIG. 2C. In the illustrated embodiment, the photovoltaic element 245 is formed above the reinforced silicone resin film 240 and may act as a substrate for the photovoltaic element 245. However, as discussed above, the reinforced silicone resin film 240 may alternatively be a superstrate for the photovoltaic element 245. The photovoltaic element 245 may include one or more layers. In the illustrated embodiment, the photovoltaic element 245 includes a molybdenum layer 250, a reflective layer 260, a photo-reactive layer 265, and a contact layer 270. As discussed above, the reflective layer 260 may be formed of zinc oxide and/or aluminum, the photo-reactive layer 265 may comprise an intermediate band gap n-i-p a-SiGe:H solar cell, and the contact layer 270 may be indium tin oxide (ITO). The completed solar cell 275 including the photovoltaic element 245 and the reinforced silicone resin film 240 may then be removed from the substrate and, if present, the release layer. Alternatively, the reinforced silicone resin film 240 may be released from the substrate 105 first. Then a similar solar cell fabrication process can be followed to produce a solar cell directly on the freestanding reinforced silicone resin films.

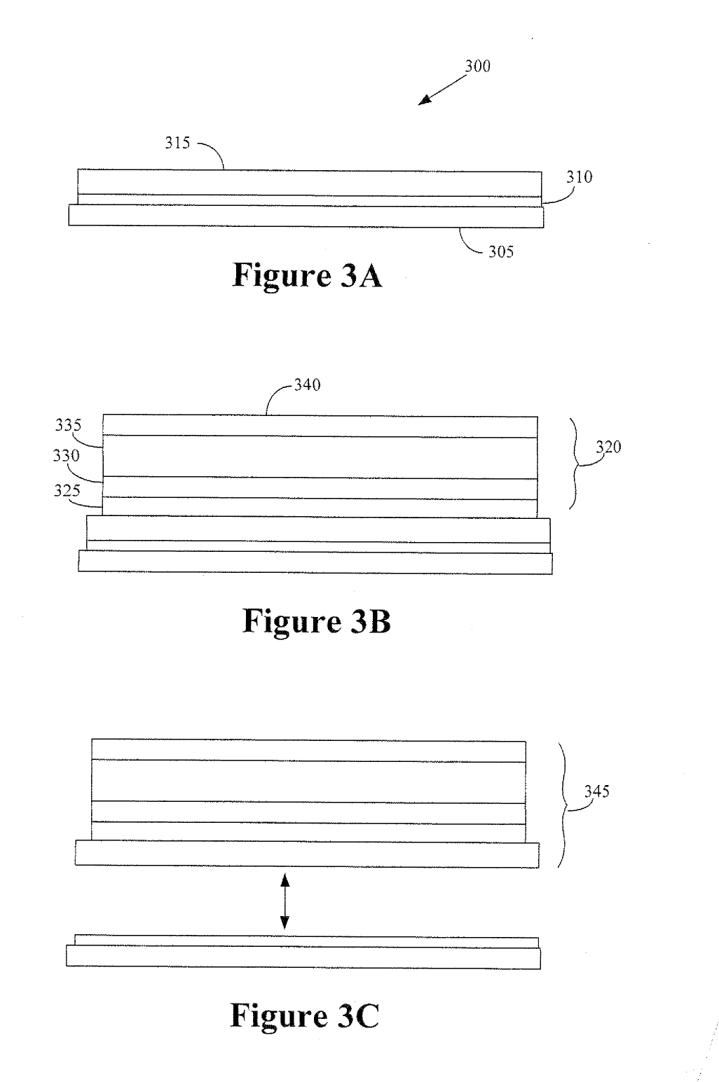

FIGS. 3A, 3B, and 3C conceptually illustrate a third exemplary embodiment of a method 300 of forming a solar cell. In the illustrated embodiment, a substrate 305 is treated to form a release layer 310 that is intended to decreased adherence of subsequently formed layers to the substrate 305 and to allow the subsequently formed layers to be released from the substrate 305. As discussed above, the release layer 310 can be any rigid or flexible material having a surface from which the reinforced silicone resin film can be removed without damage by delamination after the silicone resin is cured. Examples of release liners include, but are not limited to, Nylon, polyethyleneterephthalate, polyimide, PTFE, silicone, and sol gel coatings. Furthermore, the release layer 310 is optional and not necessary for the practice of the present invention.

A layer 315 of a curable solventless resin is then deposited over the substrate 305 or, if present, the release layer 310. Examples of resins that may be used to form the layer 315 are given above and the layer 315 may be deposited using any of the techniques described herein. In various embodiments, the curable solventless resin may be cast in a mold or a releasable substrate or coated onto a surface. The layer 315 may then be at least partially cured. For example, the layer 315 may be heated in an air circulating oven through the following process: 5° C./min. to 100° C., 100° C. stay for 1 h., 5° C./min. to 160° C., 160° C. stay for 1 h., 5° C./min. to 200° C., and 200° C. for 2 h. The resin layer 315 can also be a pre-cured resin film laid on substrate 305, or if present, release coating layer 310.

In the embodiment shown in FIG. 3C, a photovoltaic element 320 may then be formed adjacent the cured or partially cured layer 315. However, persons of ordinary skill in the art having benefit of the present disclosure should appreciate that the present invention is not limited to embodiments in which the photovoltaic element 320 is formed while the cured or partially cured layer 315 remains adjacent the substrate 305 or, if present, the release layer 310. In alternative embodiments, the cured or partially cured layer 315 may be removed from the substrate 305 or, if present, the release layer 310 prior to forming the photovoltaic element 320 adjacent the cured or partially cured layer 315. As discussed above, the photovoltaic element 320 may include a molybdenum layer 325, a reflective layer 330, a photo-reactive layer 335, and a contact layer 340. The completed solar cell 345 including the photovoltaic element 320 and the silicone resin film 315 may then be removed from the substrate 305 and, if present, the release layer 310, as shown in FIG. 3C. Alternatively, the silicone resin film 240 may be released from the substrate 105 first. Then a similar solar cell fabrication process can be followed to produce a solar cell directly on the freestanding silicone resin films.

The particular embodiments disclosed above are illustrative only, as the invention may be modified and practiced in different but equivalent manners apparent to those skilled in the art having the benefit of the teachings herein. For example, the silicone resin film may be coated onto a metal foil such as a stainless steel foil and the coated metal foil may be used as the substrate for the aforementioned solar cells. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. An apparatus, comprising:
a silicone resin film that is at least partially cured; and
a photovoltaic element formed adjacent the silicone resin film.

2. The apparatus of claim 1, wherein the silicone resin film comprises a curable elastomeric silicone composition formed using a de-volatilized polymer and at least one de-volatilized cross-linker.

3. The apparatus of claim 2, wherein the de-volatilized polymer comprises a de-volatilized vinyl functional siloxane polymer exposed to at least one of a vacuum and heat to remove volatiles from the polymer.

4. The apparatus of claim 3, wherein said at least one de-volatilized cross-linker comprises a de-volatilized methyl hydrogen siloxane polymer with SiH functional groups exposed to at least one of a vacuum and heat to remove volatiles from the cross-linker.

5. The apparatus of claim 1, wherein the silicone resin film comprises at least one fiber-reinforced silicone resin film.

6. The apparatus of claim 5, wherein said at least one fiber-reinforced silicone resin film comprises at least one silicone resin film impregnated with a fibrous material.

7. The apparatus of claim 5, wherein said at least one fiber-reinforced silicone resin film comprises a first layer of a silicon-containing composition, a fibrous material having a first side adjacent to the first layer, and a second layer of the silicon-containing composition adjacent a second side of the fibrous material, the second side being opposite the first side.

8. The apparatus of claim 7, wherein the silicon-containing composition comprises a curable elastomeric silicone composition formed using a de-volatilized polymer and at least one de-volatilized cross-linker and the fibrous material comprises a glass fabric comprising a plurality of glass fibers and a plurality of openings therebetween.

9. The apparatus of claim 1, wherein the silicone resin film is at least one of a substrate and a superstrate for the photovoltaic element.

10. The apparatus of claim 1, wherein the photovoltaic element comprises an intermediate band gap solar cell.

11. The apparatus of claim 10, wherein the intermediate band gap solar cell comprises a solar cell comprising SiGe:H.

12. The apparatus of claim 10, comprising a molybdenum layer adjacent the silicone resin film and a zinc oxide/aluminum layer adjacent to the molybdenum layer, the molybdenum layer being adjacent the intermediate band gap solar cell.

13. The apparatus of claim 12, comprising an indium tin oxide layer adjacent the intermediate band gap solar cell.

14. The apparatus of claim 1, wherein the photovoltaic element formed immediately adjacent the silicone resin film.

15. The apparatus of claim 1, wherein the silicone resin film is a coating layer on a metal foil.

16. The apparatus of claim 15, wherein the metal foil is a stainless steel foil.

17. A method, comprising:
forming a silicone resin film; and
forming a photovoltaic element adjacent the silicone resin film.

18. The method of claim 17, wherein forming the silicone resin film comprises:
depositing a curable silicone resin composition; and
curing, at least partially, the silicone resin composition to form a silicone resin film.

19. The method of claim 18, wherein depositing the curable silicone resin composition comprises depositing a curable elastomeric silicone composition comprising a de-volatilized polymer and at least one de-volatilized cross-linker.

20. The method of claim 19, wherein depositing the curable elastomeric silicone composition comprises depositing a de-volatilized vinyl functional siloxane polymer that has been exposed to at least one of a vacuum and heat to remove volatiles from the polymer.

21. The method of claim 19, wherein depositing the curable elastomeric silicone composition comprises depositing a de-volatilized methyl hydrogen siloxane polymer with SiH functional groups that has been exposed to at least one of a vacuum and heat to remove volatiles from the cross-linker.

22. The method of claim 17, wherein forming the silicone resin film comprises forming at least one fiber-reinforced silicone resin film.

23. The method of claim 22, wherein forming said at least one fiber-reinforced silicone resin film comprises impregnating said at least one silicone resin film with a fibrous material.

24. The method of claim 22, wherein forming said at least one fiber-reinforced silicone resin film comprises forming a first layer of a silicon-containing composition, positioning a fibrous material having a first side adjacent to the first layer, and forming a second layer of the silicon-containing composition adjacent a second side of the fibrous material, the second side being opposite the first side.

25. The method of claim 24, wherein forming the first or second layers of the silicon-containing composition comprises forming the first or second layers of a curable elastomeric silicone composition formed using a de-volatilized polymer and at least one de-volatilized, cross-linker.

26. The method of claim 24, wherein positioning the fibrous material comprises positioning a glass fabric comprising a plurality of glass fibers and a plurality of openings therebetween adjacent to the first layer.

27. The method of claim 17, comprising forming the silicone resin film and the photovoltaic element such that the silicone resin film is at least one of a substrate and a superstrate for the photovoltaic element.

28. The method of claim 27, wherein forming the silicone resin film comprises depositing a silicone resin or mixtures of silicone resins onto a metal foil, and at least partially curing the silicone resin.

29. The method of claim 28, wherein forming the photovoltaic element comprises forming an intermediate band gap solar cell.

30. The method of claim 29, wherein forming the intermediate band gap solar cell comprises forming a solar cell comprising SiGe:H.

31. The method of claim 29, comprising forming a molybdenum layer adjacent the silicone resin film and forming a zinc oxide/aluminum layer adjacent to the molybdenum layer, the molybdenum layer being adjacent the intermediate band gap solar cell.

32. The method of claim 29, comprising forming an indium tin oxide layer adjacent the intermediate band gap solar cell.

33. The method of claim 17, wherein forming the photovoltaic element adjacent the silicone resin film comprises forming the photovoltaic element immediately adjacent the silicone resin film.

34. A solar cell formed by a process, comprising:
forming a silicone resin film; and
forming a photovoltaic element adjacent the silicone resin film.

35. The solar cell formed by the process of claim 34, wherein forming the silicone resin film comprises:
depositing a curable silicone resin composition; and
curing, at least partially, the silicone resin composition to form a silicone resin film.

36. The solar cell formed by the process of claim 35, wherein depositing the curable silicone resin composition comprises depositing a curable elastomeric silicone composition comprising a de-volatilized polymer and at least one de-volatilized cross-linker.

37. The solar cell formed by the process of claim 36, wherein depositing the curable elastomeric silicone composition comprises depositing a de-volatilized vinyl functional siloxane polymer that has been exposed to at least one of a vacuum and heat to remove volatiles from the polymer.

38. The solar cell formed by the process of claim 36, wherein depositing the curable elastomeric silicone composition comprises depositing a de-volatilized methyl hydrogen siloxane polymer with SiH functional groups that has been exposed to at least one of a vacuum and heat to remove volatiles from the cross-linker.

39. The solar cell formed by the process of claim 34, wherein forming the silicone resin film comprises forming at least one fiber-reinforced silicone resin film.

40. The solar cell formed by the process of claim 39, wherein forming said at least one fiber-reinforced silicone resin film comprises impregnating said at least one silicone resin film with a fibrous material.

41. The solar cell formed by the process of claim 39, wherein forming said at least one fiber-reinforced silicone resin film comprises forming a first layer of a silicon-containing composition, positioning a fibrous material having a first side adjacent to the first layer, and forming a second layer of the silicon-containing composition adjacent a second side of the fibrous material, the second side being opposite the first side.

42. The solar cell formed by the process of claim 41, wherein forming the first or second layers of the silicon-containing composition comprises forming the first or second layers of a curable elastomeric silicone composition formed using a de-volatilized polymer and at least one de-volatilized cross-linker.

43. The solar cell formed by the process of claim 41, wherein positioning the fibrous material comprises positioning a glass fabric comprising a plurality of glass fibers and a plurality of openings therebetween adjacent to the first layer.

44. The solar cell formed by the process of claim 34, comprising forming the silicone resin film and the photovoltaic element such that the silicone resin film is at least one of a substrate and a superstrate for the photovoltaic element.

45. The solar cell formed by the process of claim 34, wherein forming the silicone resin film comprises depositing a silicone resin or mixtures of silicone resins onto a metal foil, and at least partially curing the silicone resin.

46. The solar cell formed by the process of claim 34, wherein forming the photovoltaic element comprises forming an intermediate band gap solar cell.

47. The solar cell formed by the process of claim 46, wherein forming the intermediate band gap solar cell comprises forming a solar cell comprising SiGe:H.

48. The solar cell formed by the process of claim 46, comprising forming a molybdenum layer adjacent the silicone resin film and forming a zinc oxide/aluminum layer adjacent to the molybdenum layer, the molybdenum layer being adjacent the intermediate band gap solar cell.

49. The solar cell formed by the process of claim 48, comprising forming an indium tin oxide layer adjacent the intermediate band gap solar cell.

50. The solar cell formed by the process of claim 34, wherein forming the photovoltaic element adjacent the silicone resin film comprises forming the photovoltaic element immediately adjacent the silicone resin film.
